(19) United States
(12) Patent Application Publication
(10) Pub. No.: US 2010/0140559 A1
(43) Pub. Date: Jun. 10, 2010

(54) MIXTURES FOR PRODUCING PHOTOACTIVE LAYERS FOR ORGANIC SOLAR CELLS AND ORGANIC PHOTODETECTORS

(75) Inventors: Meerholz Klaus, Roesrath (DE); Frank Wuerthner, Hoechberg (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASF SE, Ludwigshafen (DE)

(21) Appl. No.: 12/668,299

(22) PCT Filed: Jul. 7, 2008
(86) PCT No.: PCT/EP2008/058773

§ 371 Date: Jan. 8, 2010

(30) Foreign Application Priority Data
Jul. 10, 2007 (EP) 07112153.7

(51) Int. Cl. H01B 1/12

(52) U.S. Cl. 252/501.1; 977/735

(57) ABSTRACT

The present invention relates to the use of mixtures which comprise compounds D-A in which D is a donor moiety and A is an acceptor moiety, especially to the use of mixtures which comprise compounds D-A and fullerene derivatives, for producing photoactive layers for organic solar cells and organic photodetectors, to corresponding organic solar cells and organic photodetectors, and to mixtures which comprise compounds D-A and fullerene derivatives.

The present invention relates to the use of mixtures which comprise compounds D-A in which D is a donor moiety and A is an acceptor moiety, especially to the use of mixtures which comprise compounds D-A and fullerene derivatives, for producing photoactive layers for organic solar cells and organic photodetectors, to corresponding organic solar cells and organic photodetectors, and to mixtures which comprise compounds D-A and fullerene derivatives.

It is expected that, in the future, not only the classical inorganic semiconductors but increasingly also organic semiconductors based on low molecular weight or polymeric materials will be used in many fields of the electronics industry. In many cases, these organic semiconductors have advantages over the classical inorganic semiconductors, for example better substrate compatibility and better processibility of the semiconductor components based on them. They allow processing on flexible substrates and enable their interface orbital energies to be adjusted precisely to the particular application range by the methods of molecular modeling. The significantly reduced costs of such components have brought a renaissance to the field of research of organic electronics. Organic electronics is concerned principally with the development of new materials and manufacturing processes for the production of electronic components based on organic semiconductor layers. These include in particular organic field-effect transistors (OFETs) and organic light-emitting diodes (OLEDs; for example for use in displays), and organic photovoltaics.

The direct conversion of solar energy to electrical energy in solar cells is based on the internal photoeffect of a semiconductor material, i.e. the generation of electron hole pairs by absorption of photons and the separation of the negative and positive charge carriers at a p-n transition or a Schottky contact. The photovoltage thus generated can bring about a photocurrent in an external circuit, through which the solar cell delivers its power.

The semiconductor can absorb only those photons which have an energy which is greater than its band gap. The size of the semiconductor band gap thus determines the proportion of sunlight which can be converted to electrical energy. It is expected that, in the future, organic solar cells will outperform the classical solar cells based on silicon owing to lower costs, a lower weight, the possibility of producing flexible and/or colored cells, the better possibility of fine adjustment of the band gap. There is thus a great demand for organic semiconductors which are suitable for producing organic solar cells.

In order to utilize solar energy very effectively, organic solar cells normally consist of two absorbing materials with different electron affinity or different ionization behavior. In that case, one material functions as a p-conductor (electron donor), the other as an n-conductor (electron acceptor). The first organic solar cells consisted of a two-layer system composed of a copper phthalocyanine as a p-conductor and PTCBI as an n-conductor, and exhibited an efficiency of 1%. In order to utilize as many incident photons as possible, relatively high layer thicknesses are used (e.g. 100 nm). In order to generate current, the excited state generated by the absorbed photons must, however, reach a p-n junction in order to generate a hole and an electron, which then flows to the anode and cathode. Most organic semiconductors, however, have only diffusion lengths for the excited state of up to 10 nm. Even the best production processes known to date allow the distance over which the excited state has to be transmitted to be reduced to no less than from 10 to 30 nm.

More recent developments in organic photovoltaics have been in the direction of the so-called “bulk heterojunction”: in this case, the photoactive layer comprises the acceptor and donor compound(s) as a bicontinuous phase. As a result of photoinduced charge transfer from the excited state of the donor compound to the acceptor compound, owing to the spatial proximity of the compounds, a rapid charge separation compared to other relaxation procedures takes place, and the holes and electrons which arise are removed via the corresponding electrodes. Between the electrodes and the photoactive layer, further layers, for example hole or electron transport layers, are often applied in order to increase the efficiency of such cells.

To date, the donor materials used in such bulk heterojunction cells have usually been polymers, for example polyvinylphenylenes or polythiophenes, or dyes from the class of the phthalocyanines, e.g. zinc phthalocyanine or vanadyl phthalocyanine, and the acceptor materials used have been fullerene and fullerene derivatives and also various perylenes. Photoactive layers composed of the donor/acceptor pairs poly(3-hexyl-thiophene) (“P3HT”)/[6,6]-phenyl-C₆₁-butyric acid methyl ester (“PCBM”), poly(2-methoxy-5-(3,7-dimethyloctyloxy)-1,4-phenylenevinylene) (“OC₁C₁₀-PPV”)/PCBM and zinc phthalocyanine/fullerene have been and are being researched intensively.

It was thus an object of the present invention to provide further photoactive layers for use in electronic components, especially in organic solar cells and organic photodetectors, which are easy to produce and have a sufficient efficiency for the conversion of light energy to electrical energy in industrial applications.

Accordingly, the use has been found of mixtures comprising, as components,

K1) one or more compounds of the general formula k1

D-A (k1)

as an electron donor or electron acceptor, in which
D is a donor moiety which comprises at least one carbon-carbon or carbon-heteroatom double bond and at least one unfused or fused carbo- or heterocyclic ring,
A is an acceptor moiety which comprises at least one carbon-carbon or carbon-heteroatom double bond and at least one unfused or fused carbo- or heterocyclic ring,
   and the donor moiety D and the acceptor moiety A are u-conjugated to one another,
      and
      K2) one or more compounds which act correspondingly as electron acceptors or electron donors toward component K1)
      for producing photoactive layers for organic solar cells and organic photodetectors.

In particular, the donor moiety D in the one or more compounds of the general formula k1 is selected from the group consisting of:

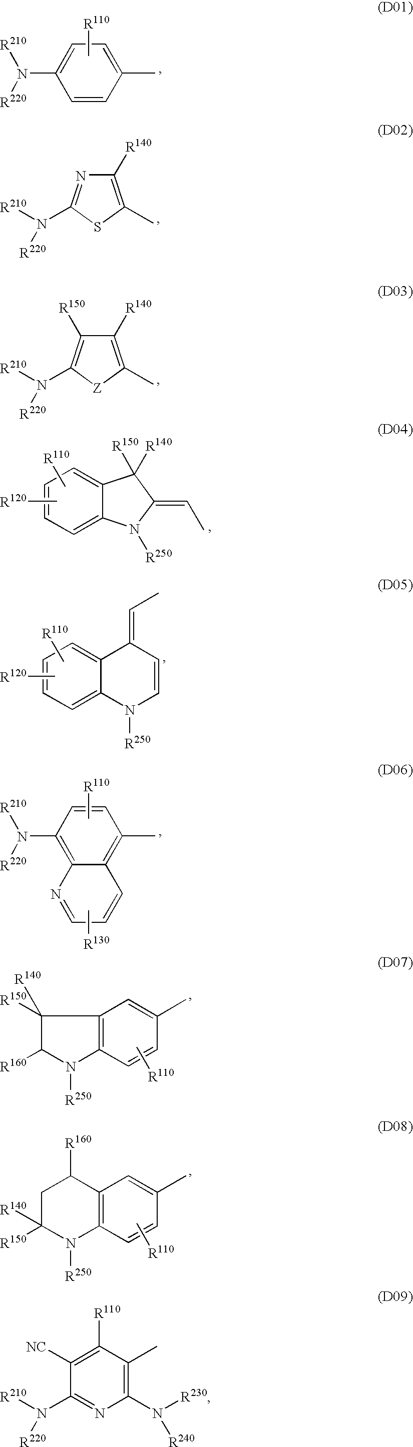

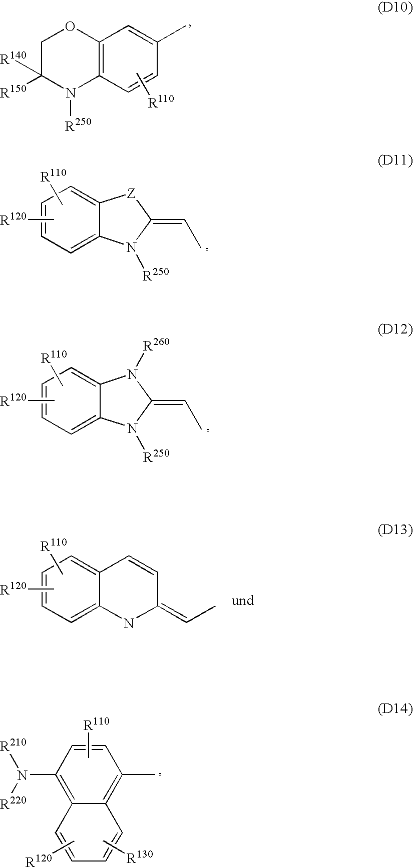

in which
R¹¹⁰, R¹²⁰ and R¹³⁰ are each independently hydrogen, halogen, hydroxyl, C₁-C₁₀-alkyl which may be interrupted by one or two nonadjacent oxygen atoms, C₅-C₇-cycloalkyl, C₁-C₁₀-alkoxy, C₁-C₁₀-alkylamino, di(C₁-C₁₀-alkyl)amino, C₁-C₁₀-alkylamino- or di(C₁-C₁₀-alkyl)aminosulfonylamino, C₁-C₁₀-alkylsulfonylamino, aryl, aryl-C₁-C₁₀-alkyl, aryloxy-C₁-C₁₀-alkyl or an —NHCOR¹⁷⁰ or —NHCOOR¹⁷⁰ radical in which R¹⁷⁰ is defined as aryl, aryl-C₁-C₁₀-alkyl or C₁-C₁₀-alkyl which may be interrupted by one or two nonadjacent oxygen atoms,
R¹⁴⁰, R¹⁵⁰ and R¹⁶⁰ are each independently hydrogen, C₁-C₁₀-alkyl which may be interrupted by one or two nonadjacent oxygen atoms, C₅-C₇-cycloalkyl or aryl,

R²¹⁰, R²²⁰, R²³⁰ and R²⁴⁰ are each independently C₁-C₁₀-alkyl which may be interrupted by one or two nonadjacent oxygen atoms, or C₅-C₇-cycloalkyl, or R²¹⁰ and R²²⁰ and/or R²³⁰ and R²⁴⁰ form, together with the nitrogen atom to which they are bonded, a five- or six-membered ring in which one CH₂ group not adjacent to the nitrogen atom may be replaced by an oxygen atom,
R²⁵⁰ and R²⁶⁰ are each independently C₁-C₁₀-alkyl which may be interrupted by one or two nonadjacent oxygen atoms, C₅-C₇-cycloalkyl, aryl, aryl-C₁-C₁₀-alkyl or aryloxy-C₁-C₁₀-alkyl and
Z is O or S.

In particular, the acceptor moiety A in the one or more compounds of the general formula k1 is selected from the group consisting of:

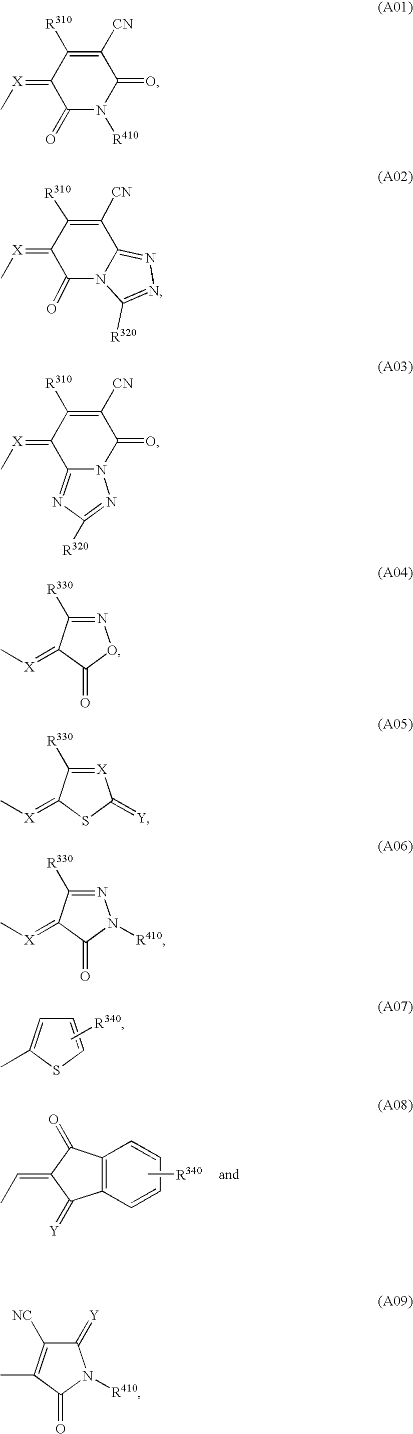

in which
R³¹⁰ and R³²⁰ are each independently hydrogen, C₁-C₁₀-alkyl which may be interrupted by one or two nonadjacent oxygen atoms, or C₅-C₇-cycloalkyl,

R³³⁰ is hydrogen, C₁-C₁₀-alkyl which may be interrupted by one or two nonadjacent oxygen atoms, partly fluorinated C₁-C₁₀-alkyl, perfluorinated C₁-C₁₀-alkyl, C₅-C₇-cycloalkyl or aryl,
R³⁴⁰ is hydrogen, NO₂, CN, COR³⁵⁰, COOR³⁵⁰, SO₂R³⁵⁰ or SO₃R³⁵⁰, in which R³⁵⁰ is defined as aryl or C₁-C₁₀-alkyl,
R⁴¹⁰ is C₁-C₁₀-alkyl which may be interrupted by one or two nonadjacent oxygen atoms, C₅-C₇-cycloalkyl, aryl, aryl-C₁-C₁₀-alkyl, aryloxy-C₁-C₁₀-alkyl, an NHCOR⁴²⁰ radical or an N(COR⁴²⁰)₂ radical, in which R⁴²⁰ is defined as aryl, aryl-C₁-C₁₀-alkyl or C₁-C₁₀-alkyl which may be interrupted by one or two nonadjacent oxygen atoms, and the two R⁴²⁰ in the —N(CO R⁴²⁰)₂ radical may be the same or different,
X is independently CH or N
   and
Y is O, C(CN)₂ or C(CN)(COOR⁴³⁰) in which R⁴³⁰ is defined as C₁-C₁₀-alkyl which may be interrupted by one or two nonadjacent oxygen atoms.

The definitions of the variables listed above are explained hereinafter and should be understood as follows.

Halogen denotes fluorine, chlorine, bromine and iodine, especially fluorine and chlorine.

C₁-C₁₀-Alkyl should be understood to mean linear or branched alkyl, for example methyl, ethyl, n-propyl, isopropyl, n-butyl, isobutyl, sec-butyl, tert-butyl, n-pentyl, n-hexyl, n-heptyl, n-octyl, 2-ethylhexyl, n-nonyl and n-decyl. Preferred groups are methyl, isopropyl, n-butyl, tert-butyl and 2-ethylhexyl; in the radicals mentioned, it is optionally possible for one or more hydrogen atoms to be replaced by fluorine atoms, such that these radicals may also be partly fluorinated or perfluorinated.

C₁-C₁₀-Alkyl which is interrupted by one or two nonadjacent oxygen atoms is, for example, 3-methoxyethyl, 2- and 3-methoxypropyl, 2-ethoxyethyl, 2- and 3-ethoxypropyl, 2-propoxyethyl, 2- and 3-propoxypropyl, 2-butoxyethyl, 2- and 3-butoxypropyl, 3,6-dioxaheptyl and 3,6-dioxaoctyl.

The C₁-C₁₀-alkoxy, C₁-C₁₀-alkylamino-, di(C₁-C₁₀-alkyl)amino, C₁-C₁₀-alkylamino-sulfonylamino-, di(C₁-C₁₀-alkyl)aminosulfonylamino and C₁-C₁₀-alkylsulfonylamino radicals are correspondingly derived from the aforementioned C₁-C₁₀-alkyl radicals, where, in the case of the di(C₁-C₁₀-alkyl)amino groups, either identical or different C₁-C₁₀alkyl radicals may be present on the amino group. Examples include methoxy, ethoxy, n-propoxy, isopropoxy, n-butoxy, isbutoxy, sec-butoxy, tert-butoxy, n-pentoxy, n-hexoxy, n-heptoxy, n-octoxy, 2-ethylhexoxy, n-nonoxy and n-decoxy, methylamino, ethylamino, n-propylamino, isopropylamino, n-butylamino, isobutylamino, sec-butylamino, tert-butylamino, n-pentylamino, n-hexylamino, n-heptylamino, n-octylamino, 2-ethylhexylamino, n-nonylamino and n-decylamino, dimethylamino, diethylamino, di(n-propyl)amino, diisopropylamino, di(n-butyl)amino, diisobutylamino, di(sec-butyl)amino, di(tert-butyl)amino, di(n-pentyl)amino, di(n-hexyl)amino, di(n-heptyl)amino, di(n-octyl)amino, di(2-ethylhexyl)amino, di(n-nonyl)amino and di(n-decyl)amino, and also the corresponding mixed dialkylamino radicals, for instance methylethylamino to methyl-n-decylamino, ethyl-n-propylamino to ethyl-n-decylamino, etc., and also methylaminosulfonylamino, ethylaminosulfonylamino, n-propyl-aminosulfonylamino, isopropylaminosulfonylamino, n-butylaminosulfonylamino, isobutylaminosulfonylamino, sec-butylaminosulfonylamino, tert-butylaminosulfonylamino, n-pentylaminosulfonylamino, n-hexylaminosulfonylamino, n-heptylaminosulfonylamino, n-octylaminosulfonylamino, 2-ethylhexylaminosulfonyl-amino, n-nonylaminosulfonylamino and n-decylaminosulfonylamino, dimethylaminosulfonylamino, diethylaminosulfonylamino, di(n-propyl)aminosulfonylamino, diisopropylaminosulfonylamino, di(n-butyl)aminosulfonylamino, diisobutylaminosulfonylamino, di(sec-butyl)amino-sulfonylamino, di(tert-butyl)aminosulfonylamino, di(n-pentyl)aminosulfonylamino, di(n-hexyl)aminosulfonylamino, di(n-heptyl)aminosulfonylamino, di(n-octyl)aminosulfonylamino, di(2-ethylhexyl)aminosulfonylamino, di(n-nonyl)amino-sulfonylamino and di(n-decyl)aminosulfonylamino, and also the corresponding radicals comprising mixed dialkylamino radicals, for instance methylethylaminosulfonylamino to methyl-n-decylaminosulfonylamino, ethyl-n-propylaminosulfonylamino to ethyl-n-decylaminosulfonylamino etc., up to n-nonyl-n-decylaminosulfonylamino, and also methylsulfonylamino, ethylsulfonylamino, n-propylsulfonylamino, isopropylsulfonylamino, n-butylsulfonylamino, isobutylsulfonylamino, sec-butylsulfonylamino, tert-butylsulfonylamino, n-pentylsulfonylamino, n-hexylsulfonylamino, n-heptylsulfonylamino, n-octylsulfonylamino, 2-ethylhexylsulfonylamino, n-nonylsulfonylamino and n-decylsulfonylamino.

C₅-C₇-Cycloalkyl is understood to mean especially cyclopentyl, cyclohexyl and cycloheptyl.

Aryl comprises mono- or polycyclic aromatic hydrocarbon radicals which may be unsubstituted or substituted. Aryl is preferably phenyl, tolyl, xylyl, mesityl, duryl, naphthyl, fluorenyl, anthracenyl, phenanthrenyl or naphthyl, more preferably phenyl or naphthyl, where these aryl groups, in the case of substitution, may bear generally 1, 2, 3, 4 or 5, preferably 1, 2 or 3, substituents which are selected from the group of radicals consisting of C₁-C₁₀-alkyl, C₁-C₁₀-alkoxy, cyano, nitro, SO₂NR^{a}R^{b}, NHSO₂NR^{a}R^{b}, CONR^{a}R^{b} and CO₂R^{a}, where the C₁-C₁₀-alkoxy groups derive from the C₁-C₁₀-alkyl groups listed above. R^{a} and R^{b} are preferably each independently hydrogen or C₁-C₁₀-alkyl.

The aryl-C₁-C₁₀-alkyl and aryloxy-C₁-C₁₀-alkyl groups derive from the alkyl and aryl groups listed above by formal replacement of one hydrogen atom of the linear or branched alkyl chain by an aryl or aryloxy group. Preferred groups here are benzyl and linear aryloxy-C₁-C₁₀-alkyl, where, in the case of C₂-C₁₀-alkyl radicals, the aryloxy radical is preferably bonded terminally.

In the photoactive layers, component K1 can assume the role of the electron donor, in which case the role of the electron acceptor is correspondingly assigned to component K2. Alternatively, though, component K1 may also assume the role of the electron acceptor, in which case component K2 functions correspondingly as the electron donor. The manner in which the particular component acts depends on the energy of the HOMO or LUMO of component K1 in relation to the energy of the HOMO or LUMO of component K2. The compounds of component K1, especially the compounds with the preferred donor moieties D01 to D14 and acceptor moieties A01 to A09 listed above, are typically merocyanines which typically appear as electron donors. In particular, this is the case when rylene or fullerene derivatives find use as component K2, which then generally act as electron acceptors. In the specific individual case, these roles may, however, be switched. It should also be pointed out that component K2 can likewise obey the structural definition of component K1, such that one compound of the formula D-A can assume the role of the electron donor and another compound of the formula D-A the role of the electron acceptor.

The mixtures which find use in accordance with the invention are preferably those in which the compounds of the general formula k1 or the preferred compounds in which the donor moieties D and/or the acceptor compounds A each have the definition of the D01 to D14 or A01 to 09 moieties detailed above each have a molecular mass of not more then 1000 g/mol, especially not more than 600 g/mol.

The mixtures which find use are also especially those, taking account of the preferences detailed above, in which component K2 comprises one or more fullerenes and/or fullerene derivatives.

Possible fullerenes include C₆₀, C₇₀, C₇₆, C₈₀, C₈₂, C₈₄, C₈₆, C₉₀ and C₉₄, especially C₆₀ and C₇₀. An overview of fullerenes which can be used in accordance with the invention is given, for example, by the monograph by A. Hirsch, M. Brettreich, “Fullerenes: Chemistry and Reactions”, Wiley-VCH, Weinheim 2005.

The fullerene derivatives are obtained typically by reaction at one or more of the carbon-carbon double bonds present in the fullerenes, the character of the fullerene unit in the resulting derivatives being essentially unchanged.

Taking account of the preferences detailed above, the mixtures used in accordance with the invention are especially those in which component K2 comprises one or more C₆₀-fullerene derivatives of the general formula k2

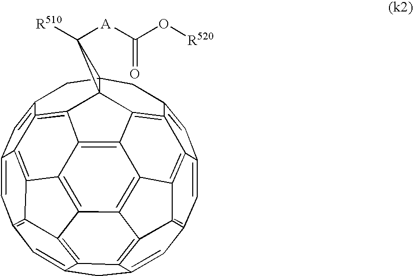

in which
A is C₁-C₁₀-alkylene,
R⁵¹⁰ is aryl or aryl-C₁-C₁₀-alkyl
and
   R⁵²⁰ is C₁-C₁₀-alkyl.

For the definition of aryl, aryl-C₁-C₁₀-alkyl and C₁-C₁₀-alkyl, reference is made to the statements already made above.

C₁-C₁₀-Alkylene is understood to mean especially a linear chain —(CH₂)ₙ— where n is 1, 2, 3, 4, 5, 6, 7, 8, 9 or 10.

In particular, in accordance with the invention, the fullerene derivatives which find use are those in which R⁵²⁰ denotes a C₁-C₄-alkyl radical, especially a methyl radical, A is a propylene chain —(CH₂)₃— and R⁵¹⁰ is an optionally substituted phenyl or 2-thienyl. The fullerene derivative is preferably [6,6]-phenyl-C₆₁-butyric acid methyl ester (“PCBM”).

Compounds of the formula k1 to be used with particular preference arise through combination of the preferred donor moieties D01 to D14 with the preferred acceptor moieties A01 to A09. The resulting compounds are represented in simplified notation by

### D01-A01, D01-A02, D01-A03, D01-A04, D01-A05, D0′-A06, D01-A07, D01-A08, D01-A09,

### D02-A01, D02-A02, D02-A03, D02-A04, D02-A05, D02-A06, D02-A07, D02-A08, D02-A09,

### D03-A01, D03-A02, D03-A03, D03-A04, D03-A05, D03-A06, D03-A07, D03-A08, D03-A09,

### D04-A01, D04-A02, D04-A03, D04-A04, D04-A05, D04-A06, D04-A07, D04-A08, D04-A09,

### D05-A01, D05-A02, D05-A03, D05-A04, D05-A05, D05-A06, D05-A07, D05-A08, D05-A09,

### D06-A01, D06-A02, D06-A03, D06-A04, D06-A05, D06-A06, D06-A07, D06-A08, D06-A09,

### D07-A01, D07-A02, D07-A03, D07-A04, D07-A05, D07-A06, D07-A07, D07-A08, D07-A09,

### D08-A01, D08-A02, D08-A03, D08-A04, D08-A05, D08-A06, D08-A07, D08-A08, D08-A09,

### D09-A01, D09-A02, D09-A03, D09-A04, D09-A05, D09-A06, D09-A07, D09-A08, D09-A09,

### D10-A01, D10-A02, D10-A03, D10-A04, D10-A05, D10-A06, D10-A07, D10-A08, D10-A09,

### D11-A01, D11-A02, D11-A03, D11-A04, D11-A05, D11-A06, D11-A07, D11-A08, D11-A09,

### D12-A01, D12-A02, D12-A03, D12-A04, D12-A05, D12-A06, D12-A07, D12-A08, D12-A09,

### D13-A01, D13-A02, D13-A03, D13-A04, D13-A05, D13-A06, D13-A07, D13-A08, D13-A09,

### D14-A01, D14-A02, D14-A03, D14-A04, D14-A05, D14-A06, D14-A07, D14-A08 and D14-A09.

Very particular preference is given to using the compounds of the combination

### D01-A01, D01-A02, D01-A03, D01-A04, D01-A05, D01-A06, D01-A07, D01-A08, D01-A09,

### D02-A01, D02-A02, D02-A03, D02-A04, D02-A05, D02-A06, D02-A07, D02-A08, D02-A09,

### D03-A01, D03-A02, D03-A03, D03-A04, D03-A05, D03-A06, D03-A07, D03-A08, D03-A09,

### D04-A01, D04-A02, D04-A03, D04-A04, D04-A05, D04-A06, D04-A07, D04-A08, D04-A09,

### D05-A01, D05-A02, D05-A03, D05-A04, D05-A05, D05-A06, D05-A07, D05-A08, D05-A09,

### D06-A01, D06-A02, D06-A03, D06-A04, D06-A05, D06-A06, D06-A07, D06-A08 and

D06-A09.

The compounds shown explicitly below are D01-A01, D01-A02, D01-A03, D01-A04, D01-A05, D01-A06, D01-A07, D01-A08 and D01-A09

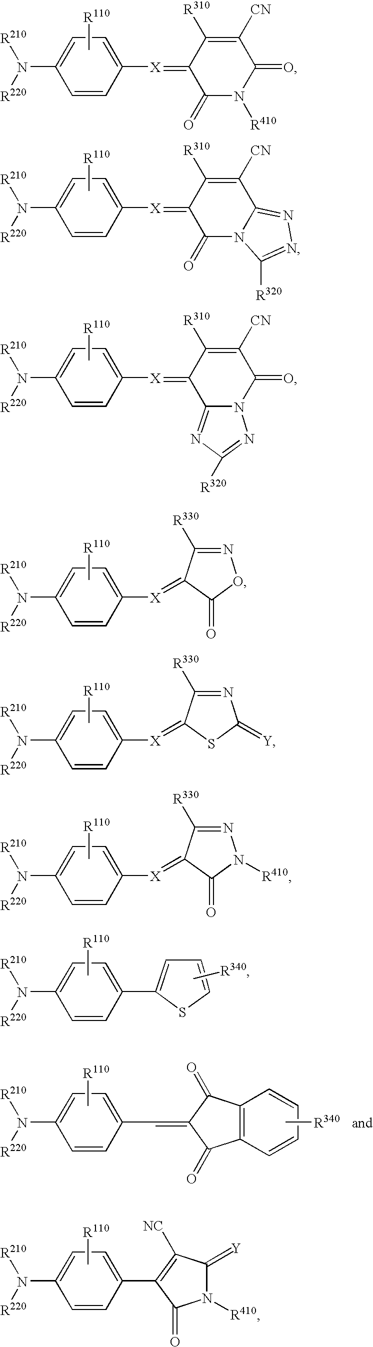

the compounds D02-A01, D02-A02, D02-A03, D02-A04, D02-A05, D02-A06, D02-A07,

D02-A08 and D02-A09

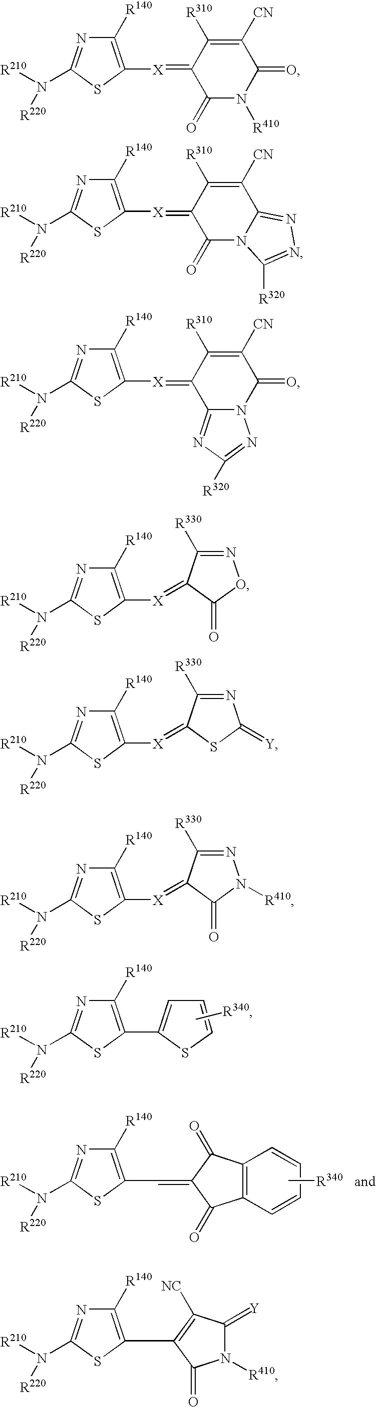

the compounds D03-A01, D03-A02, D03-A03, D03-A04, D03-A05, D03-A06, D03-A07, D03-A08 and D03-A09

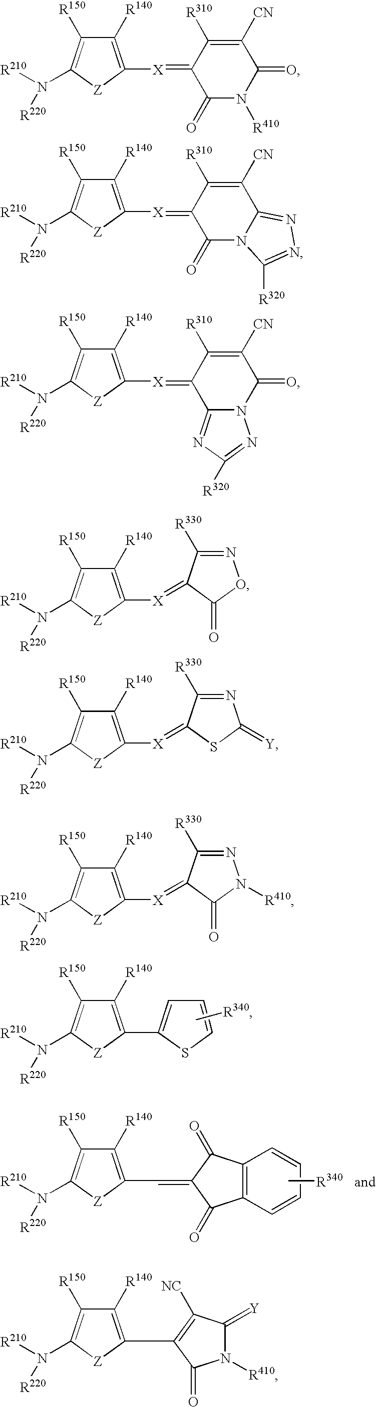

the compounds D04-A01, D04-A02, D04-A03, D04-A04, D04-A05, D04-A06, D04-A07, D04-A08 and D04-A09

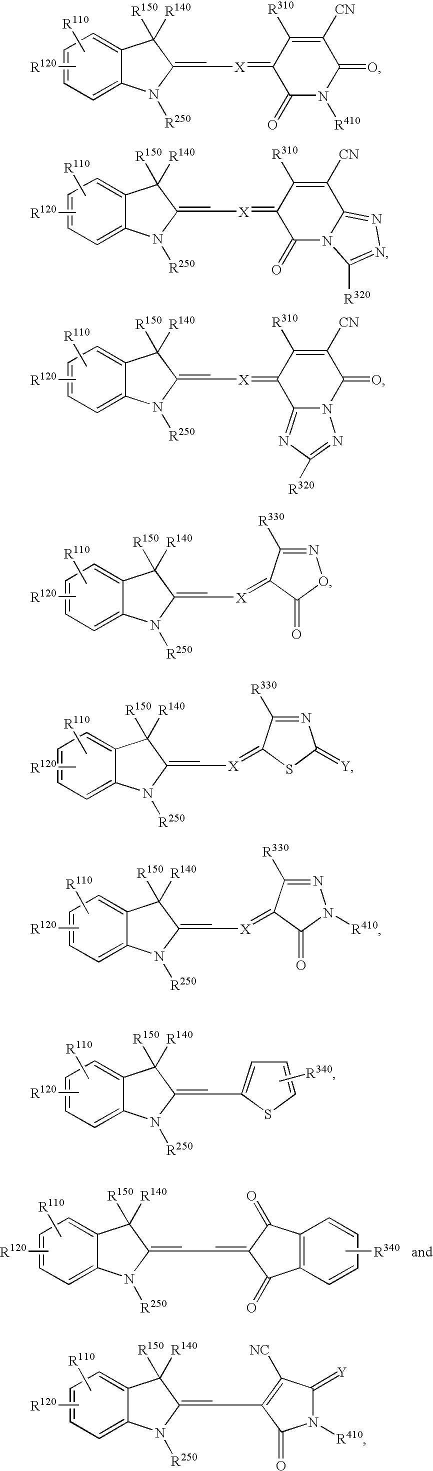

the compounds D05-A01, D05-A02, D05-A03, D05-A04, D05-A05, D05-A06, D05-A07, D05-A08 and D05-A09

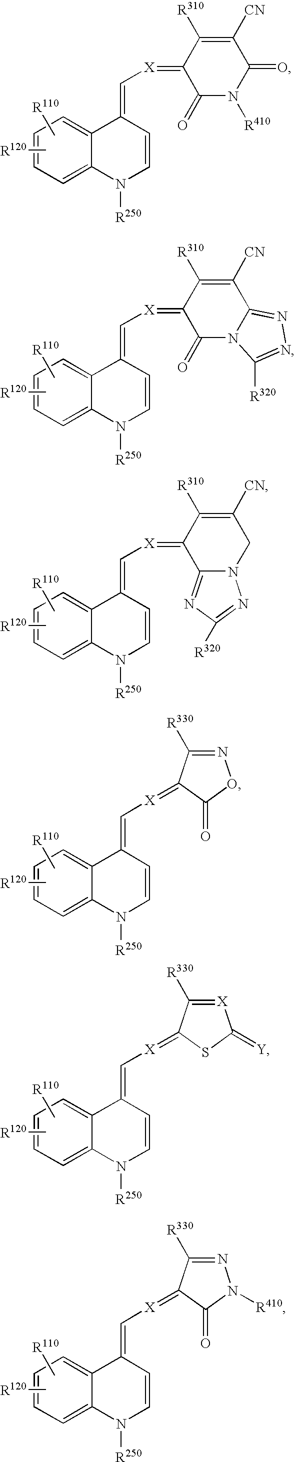

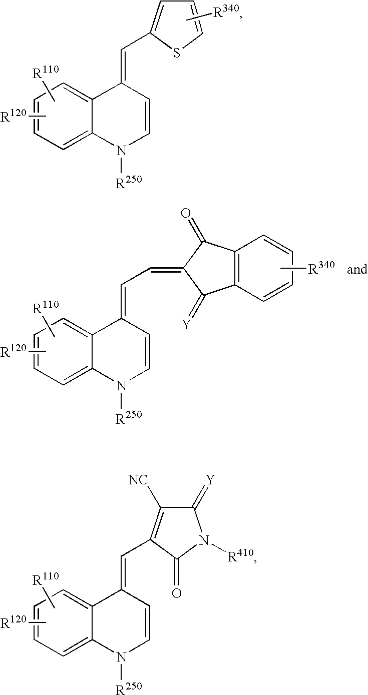

and the compounds D06-A01, D06-A02, D06-A03, D06-A04, D06-A05, D06-A06, D06-A07, D06-A08 and D06-A09

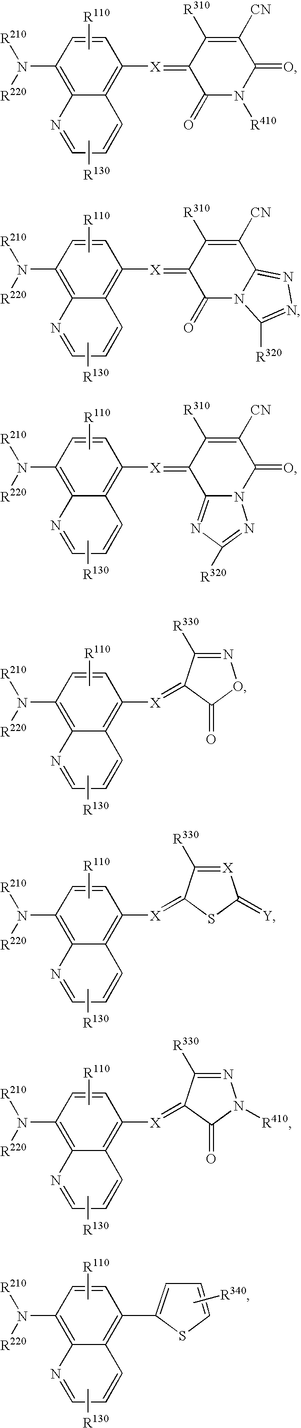

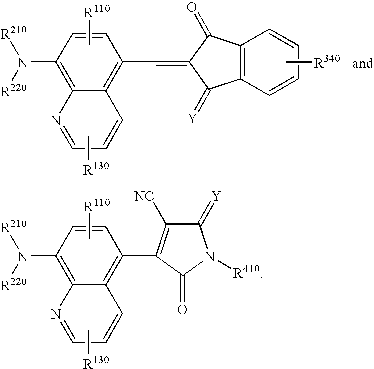

The variables here are each as defined above.

As a result of the preparation, it is possible in the individual case that a compound shown explicitly is not obtained, but rather an isomeric compound thereof, or that mixtures of isomers are also obtained. According to the invention, the isomeric compounds of the formula k1 or the isomers of the corresponding preferred and particularly preferred compounds, and also mixtures of isomers, shall accordingly also be comprised.

The synthesis of the compounds of the general formula k1, especially the synthesis of the compounds of the formulae shown above

### D01-A01, D01-A02, D01-A03, D01-A04, D01-A05, D01-A06, D01-A07, D01-A08, D01-A09,

### D02-A01, D02-A02, D02-A03, D02-A04, D02-A05, D02-A06, D02-A07, D02-A08, D02-A09,

### D03-A01, D03-A02, D03-A03, D03-A04, D03-A05, D03-A06, D03-A07, D03-A08, D03-A09,

### D04-A01, D04-A02, D04-A03, D04-A04, D04-A05, D04-A06, D04-A07, D04-A08, D04-A09,

### D05-A01, D05-A02, D05-A03, D05-A04, D05-A05, D05-A06, D05-A07, D05-A08, D05-A09,

### D06-A01, D06-A02, D06-A03, D06-A04, D06-A05, D06-A06, D06-A07, D06-A08 and D06-A09

is known to those skilled in the art, or they can be prepared on the basis of known synthesis methods.

In particular, with regard to corresponding syntheses, the following publications should be mentioned:
DE 195 02 702 A1;
EP 416 434 A2;
EP 509 302 A1;
“ATOP Dyes. Optimization of a Multifunctional Merocyanine Chromophore for High Refractive Index Modulation in Photorefractive Materials”, F. Würthner, S. Yao, J. Schilling, R. Wortmann, M. Redi-Abshiro, E. Mecher, F. Gallego-Gomez, K. Meerholz, J. Am. Chem. Soc. 2001, 123, 2810-2814;
“Merocyaninfarbstoffe im Cyaninlimit: eine neue Chromophorklasse für photorefraktive Materialien; Merocyanine Dyes in the Cyanine Limit: A New Class of Chromophores for Photorefractive Materials”, F. Wurthner, R. Wortmann, R. Matschiner, K. Lukaszuk, K. Meerholz, Y. De Nardin, R. Bittner, C. Bräuchle, R. Sens, Angew. Chem. 1997, 109, 2933-2936; Angew. Chem. Int. Ed. Engl. 1997, 36, 2765-2768;
“Electrooptical Chromophores for Nonlinear Optical and Photorefractive Applications”, S. Beckmann, K.-H. Etzbach, P. Krämer, K. Lukaszuk, R. Matschiner, A. J. Schmidt, P. Schuhmacher, R. Sens, G. Seybold, R. Wortmann, F. Würthner, Adv. Mater. 1999, 11, 536-541;
“DMF in Acetic Anhydride: A Useful Reagent for Multiple-Component Syntheses of Merocyanine Dyes”, F. Würthner, Synthesis 1999, 2103±2113;
Ullmann's Encyclopedia of industrial Chemistry, Vol. 16, 5^{th} Edition (Ed. B. Elvers, S. Hawkins, G. Schulz), VCH 1990 in the chapter “Methine Dyes and Pigments”, p. 487-535 by R. Raue (Bayer AG).

The mixtures which find use in accordance with the invention are preferably those wherein component K1 is present in a proportion of from 10 to 90% by mass, and component K2 in a proportion of from 90 to 10% by mass, where the proportions of components K1 and K2, based in each case on the overall composition of components K1 and K2, add up to 100% by mass.

The mixtures used are more preferably those wherein component K1 is present in a proportion of from 20 to 80% by mass, and component K2 in a proportion of from 80 to 20% by mass, where the proportions of components K1 and K2, based in each case on the overall composition of components K1 and K2, again add up to 100% by mass.

Also claimed in the context of the present invention are organic solar cells and organic photodetectors which comprise photoactive layers which have been produced using the above-described mixtures comprising components K1 and K2, or using the preferred embodiments of the mixtures which have likewise been described above.

Organic solar cells usually have a layered structure and comprise generally at least the following layers: electrode, photoactive layer and counterelectrode. These layers are generally present on a substrate customary for this purpose. Suitable substrates are, for example, oxidic materials, for example glass, quartz, ceramic, SiO₂, etc., polymers, for instance polyvinyl chloride, polyolefins, e.g. polyethylene and polypropylene, polyesters, fluoropolymers, polyamides, polyurethanes, polyalkyl(meth)acrylates, polystyrene and mixtures and composites thereof, and combinations of the substrates listed above.

Suitable materials for one electrode are especially metals, for example the alkali metals Li, Na, K, Rb and Cs, the alkaline earth metals Mg, Ca and Ba, Pt, Au, Ag, Cu, Al, In, metal alloys, for example based on Pt, Au, Ag, Cu, etc., and specific Mg/Ag alloys, but additionally also alkali metal fluorides such as LiF, NaF, KF, RbF and CsF, and mixtures of alkali metal fluorides and alkali metals. The electrode used is preferably a material which essentially reflects the incident light. Examples include metal films composed of Al, Ag, Au, In, Mg, Mg/Al, Ca, etc.

The counterelectrode consists of a material essentially transparent toward incident light, for example ITO, doped ITO, ZnO, TiO₂, Cu, Ag, Au and Pt, the latter materials being present in correspondingly thin layers.

In this context, an electrode/counterelectrode shall be considered to be “transparent” when at least 50% of the radiation intensity in the wavelength range in which the photoactive layer absorbs radiation is transmitted. In the case of a plurality of photoactive layers, an electrode/counterelectrode shall be considered to be “transparent” when at least 50% of the radiation intensity in the wavelength ranges in which the photoactive layers absorb is transmitted.

In addition to the photoactive layer, it is possible for one or more further layers to be present in the inventive organic solar cells and photodetectors, for example electron transporting layers (“ETLs”) and/or hole transporting layers (“HTLs”) and/or blocking layers, e.g. exciton blocking layers (“EBLs”) which typically do not absorb the incident light, or else layers which serve as charge transport layers and simultaneously improve the contacting to one or both electrodes of the solar cell. The ETLs and HTLs may also be doped, so as to give rise to cells of the p-i-n type, as described, for example, in the publication by J. Drechsel et al., Thin Solid Films 451-452 (2004), 515-517.

The construction of organic solar cells is additionally described, for example, in the documents WO 2004/083958 A2, US 2005/0098726 A1 and US 2005/0224905 A1, which are hereby fully incorporated by reference.

Photodetectors essentially have a structure analogous to organic solar cells, but are operated with suitable bias voltage which generates a corresponding current flow as a measurement response under the action of radiative energy.

The photoactive layers are processed, for example, from solution. In this case, components K1 and K2 may already be dissolved together, but may also be present separately as a solution of component K1 and a solution of component K2, in which case the corresponding solutions are mixed just before application to the layer below. The concentrations of components K1 and K2 generally vary from a few g/l to a few tens of g/l of solvent.

Suitable solvents are all liquids which evaporate without residue and have a sufficient solubility for components K1 and K2. Useful examples include aromatic compounds, for example benzene, toluene, xylene, mesitylene, chlorobenzene or dichlorobenzene, trialkylamines, nitrogen-containing heterocycles, N,N-disubstituted aliphatic carboxamides, for instance dimethylformamide, diethylformamide, dimethylacetamide or dimethylbutyramide, N-alkyllactams, for instance N-methylpyrrolidone, linear and cyclic ketones, for instance methyl ethyl ketone, cyclopentanone or cyclohexanone, cyclic ethers, for instance tetrahydrofuran, or alcohols, for instance methanol, ethanol, propanol, isopropanol or butanol.

In addition, it is also possible for mixtures of the aforementioned solvents to find use.

Suitable methods for applying the inventive photoactive layers from the liquid phase are known to those skilled in the art. What is found to be advantageous here is especially processing by means of spin-coating, since the thickness of the photoactive layer can be controlled in a simple manner by the amount and/or concentration of the solution used, and also the rotation speed and/or rotation time. The solution is generally processed at room temperature.

Moreover, in the case of suitable selection of components K1 and K2, processing from the gas phase is also possible, especially by vacuum sublimation.

In the context of the present invention, mixtures are also claimed which comprise, as components,

K1) one or more compounds of the general formula k1

D-A (k1)

in which
D is a donor moiety which comprises at least one carbon-carbon or carbon-heteroatom double bond and at least one unfused or fused carbo- or heterocyclic ring,
A is an acceptor moiety which comprises at least one carbon-carbon or carbon-heteroatom double bond and at least one unfused or fused carbo- or heterocyclic ring,
   and the donor moiety D and the acceptor moiety A are 7-conjugated to one another,
      and
      K2) one or more fullerenes and/or fullerene derivatives.

Preferred inventive mixtures comprise, as components,

K1) one or more compounds of the general formula k1

D-A (k1)

in which
D is a donor moiety which comprises at least one carbon-carbon or carbon-heteroatom double bond and at least one unfused or fused carbo- or heterocyclic ring,
A is an acceptor moiety which comprises at least one carbon-carbon or carbon-heteroatom double bond and at least one unfused or fused carbo- or heterocyclic ring,
   and the donor moiety D and the acceptor moiety A are π-conjugated to one another,
      and
      K2) comprises one or more C₆₀-fullerene derivatives of the general formula k2

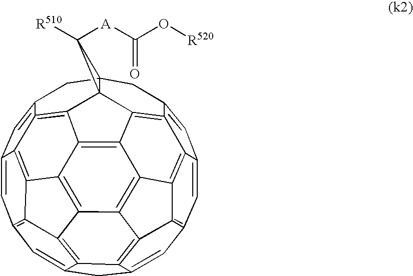

in which
A is C₁-C₁₀-alkylene,
R⁵¹⁰ is aryl or aryl-C₁-C₁₀-alkyl
and
   R⁵²⁰ is C₁-C₁₀-alkyl.

The definition and preferences for the aforementioned variables have already been discussed in detail above.

In particularly preferred inventive mixtures, taking account of the aforementioned preferences,

the donor moiety D in the one or more compounds of the general formula k1 is selected from the group consisting of:

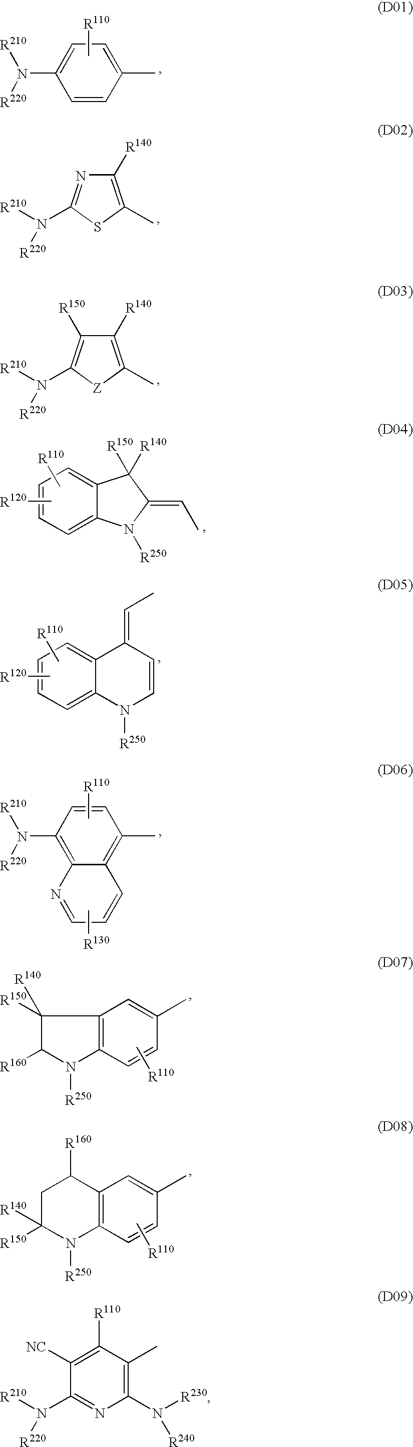

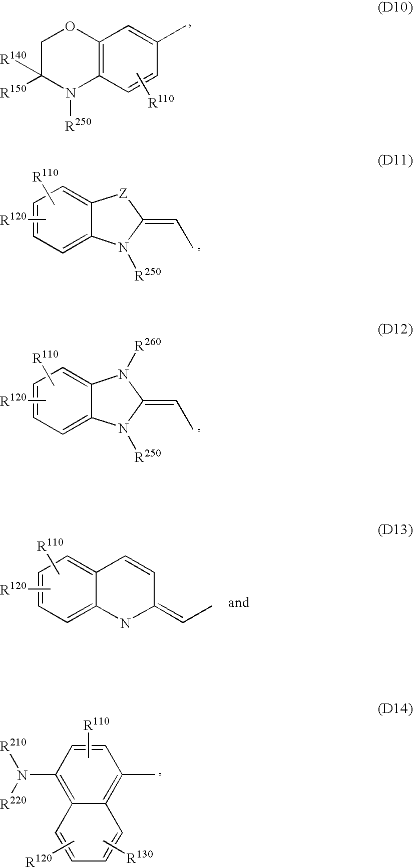

in which
R¹¹⁰, R¹²⁰ and R¹³⁰ are each independently hydrogen, halogen, hydroxyl, C₁-C₁₀-alkyl which may be interrupted by one or two nonadjacent oxygen atoms, C₅-C₇-cycloalkyl, C₁-C₁₀-alkoxy, C₁-C₁₀-alkylamino, di(C₁-C₁₀-alkyl)amino, C₁-C₁₀-alkylamino- or di(C₁-C₁₀-alkyl)aminosulfonylamino, C₁-C₁₀-alkylsulfonylamino, aryl, aryl-C₁-C₁₀-alkyl, aryloxy-C₁-C₁₀-alkyl or an —NHCOR¹⁷⁰ or —NHCOOR¹⁷⁰ radical in which R¹⁷⁰ is defined as aryl, aryl-C₁-C₁₀-alkyl or C₁-C₁₀-alkyl which may be interrupted by one or two nonadjacent oxygen atoms,
R¹⁴⁰, R¹⁵⁰ and R¹⁶⁰ are each independently hydrogen, C₁-C₁₀-alkyl which may be interrupted by one or two nonadjacent oxygen atoms, C₅-C₇-cycloalkyl or aryl,
R²¹⁰, R²²⁰, R²³⁰ and R²⁴⁰ are each independently C₁-C₁₀-alkyl which may be interrupted by one or two nonadjacent oxygen atoms, or C₅-C₇-cycloalkyl, or R²¹⁰ and R²²⁰ and/or R²³⁰ and R²⁴⁰ form, together with the nitrogen atom to which they are bonded, a five- or six-membered ring in which one CH₂ group not adjacent to the nitrogen atom may be replaced by an oxygen atom,
R²⁵⁰ and R²⁶⁰ are each independently C₁-C₁₀-alkyl which may be interrupted by one or two nonadjacent oxygen atoms, C₅-C₇-cycloalkyl, aryl, aryl-C₁-C₁₀-alkyl or aryloxy-C₁-C₁₀-alkyl
   and
Z is O or S
   and
   the acceptor moiety A in the one or more compounds of the general formula k1 is selected from the group consisting of:

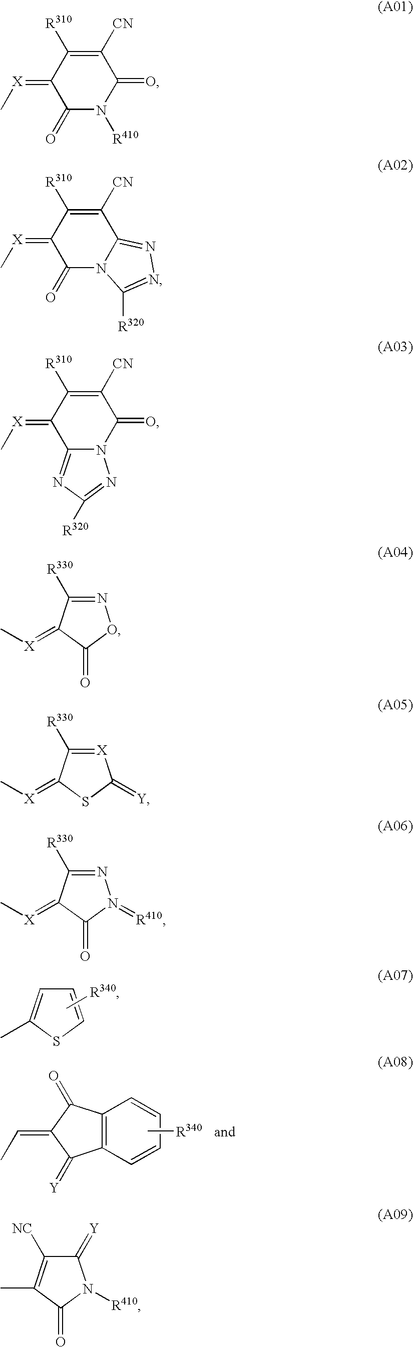

in which
are each independently hydrogen, C₁-C₁₀-alkyl which may be interrupted by one or two nonadjacent oxygen atoms, or C₅-C₇-cycloalkyl,

R³³⁰ is hydrogen, C₁-C₁₀-alkyl which may be interrupted by one or two nonadjacent oxygen atoms, partly fluorinated C₁-C₁₀-alkyl, perfluorinated C₁-C₁₀-alkyl, C₅-C₇-cycloalkyl or aryl,
R³⁴⁰ is hydrogen, NO₂, CN, COR³⁵⁰, COOR³⁵⁰, SO₂R³⁵⁰ or SO₃R³⁵⁰, in which R³⁵⁰ is defined as aryl or C₁-C₁₀-alkyl,

R⁴¹⁰ is C₁-C₁₀-alkyl which may be interrupted by one or two nonadjacent oxygen atoms, C₅-C₇-cycloalkyl, aryl, aryl-C₁-C₁₀-alkyl, aryloxy-C₁-C₁₀-alkyl, an —NHCOR⁴²⁰ radical or an —N(CO R⁴²⁰)₂ radical, in which R⁴²⁰ is defined as aryl, aryl-C₁-C₁₀-alkyl or C₁-C₁₀-alkyl which may be interrupted by one or two nonadjacent oxygen atoms, and the two R⁴²⁰ in the —N(CO R⁴²⁰)₂ radical may be the same or different,
X is independently CH or N
   and
Y is O, C(CN)₂ or C(CN)(COOR⁴³⁰) in which R⁴³⁰ is defined as C₁-C₁₀-alkyl which may be interrupted by one or two nonadjacent oxygen atoms.

The corresponding very particularly preferred compounds

### D01-A01, D01-A02, D01-A03, D01-A04, D01-A05, D01-A06, D01-A07, D01-A08, D01-A09,

### D02-A01, D02-A02, D02-A03, D02-A04, D02-A05, D02-A06, D02-A07, D02-A08, D02-A09,

### D03-A01, D03-A02, D03-A03, D03-A04, D03-A05, D03-A06, D03-A07, D03-A08, D03-A09,

### D04-A01, D04-A02, D04-A03, D04-A04, D04-A05, D04-A06, D04-A07, D04-A08, D04-A09,

### D05-A01, D05-A02, D05-A03, D05-A04, D05-A05, D05-A06, D05-A07, D05-A08, D05-A09,

### D06-A01, D06-A02, D06-A03, D06-A04, D06-A05, D06-A06, D06-A07, D06-A08 and D06-A09

have already been listed above; reference is made explicitly to them also in relation to the inventive mixtures.

Furthermore, and taking account of the aforementioned preferences, those inventive mixtures are claimed, wherein component K1 is present in a proportion of from 10 to 90% by mass, and component K2 in a proportion of from 90 to 10% by mass, where the proportions of components K1 and K2, based in each case on the overall composition of components K1 and K2, add up to 100% by mass.

In particular, and taking account of the aforementioned preferences, in those inventive mixtures claimed, component K1 is present in a proportion of from 20 to 80% by mass, and component K2 in a proportion of from 80 to 20% by mass, where the proportions of components K1 and K2, based in each case on the overall composition of components K1 and K2, add up to 100% by mass.

The invention will be illustrated in detail with reference to the nonrestrictive examples which follow.

### EXAMPLES

Compounds used as Component K1 in the Inventive Photoactive Layers:

### Compound of the Formula D02-A01:

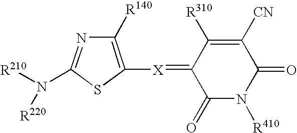

| Abbreviation | X | R²¹⁰ | R²²⁰ | R¹⁴⁰ | R³¹⁰ | R⁴¹⁰ |
|---|---|---|---|---|---|---|
| TAOP | CH | n-butyl | n-butyl | phenyl | methyl | n-butyl |

### Compound of the Formula D02-A04:

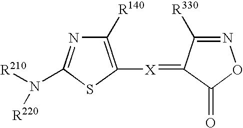

| Abbreviation | X | R²¹⁰ | R²²⁰ | R¹⁴⁰ | R³³⁰ |
|---|---|---|---|---|---|
| TAOX | CH | n-butyl | n-butyl | phenyl | phenyl |

### Compounds of the Formula D03-A01:

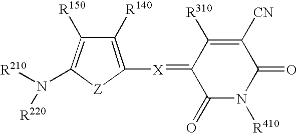

| Abbre- | | | | | | | | |
|---|---|---|---|---|---|---|---|---|
| viation | Z | X | R²¹⁰ | R²²⁰ | R¹⁴⁰ | R¹⁵⁰ | R³¹⁰ | R⁴¹⁰ |
| AFOP | O | CH | n-butyl | n-butyl | H | H | methyl | n-butyl |
| ATOP1 | S | CH | n-butyl | n-butyl | H | H | methyl | n-butyl |
| ATOP4 | S | CH | n-butyl | n-butyl | H | H | methyl | 2-ethyl- |
| | | | | | | | | hexyl |
| ATOP7 | S | CH | ethyl | n-butyl | H | H | methyl | n-butyl |
| ATOP8 | S | CH | ethyl | n-butyl | H | H | methyl | n-hexyl |

### Compound of the Formula D03-A04:

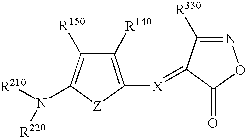

| Abbreviation | Z | X | R²¹⁰ | R²²⁰ | R¹⁴⁰ | R¹⁵⁰ | R³³⁰ |
|---|---|---|---|---|---|---|---|
| AFOX | O | CH | n-butyl | n-butyl | H | H | phenyl |

### Compounds of the Formula D04-A01:

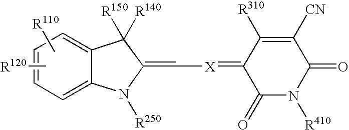

| Abbreviation | X | R²⁵⁰ | R¹¹⁰ | R¹²⁰ | R¹⁴⁰ | R¹⁵⁰ | R³¹⁰ | R⁴¹⁰ |
|---|---|---|---|---|---|---|---|---|
| IDOP301 | CH | n-butyl | H | H | methyl | methyl | methyl | 2-ethyl-hexyl |
| IDOP305 | CH | isopropyl | H | H | methyl | methyl | methyl | 2-ethyl-hexyl |

### Compounds of the Formula D04-A05:

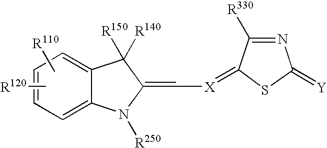

| Abbreviation | X | R²⁵⁰ | R¹¹⁰ | R¹²⁰ | R¹⁴⁰ | R¹⁵⁰ | R³³⁰ | Y |
|---|---|---|---|---|---|---|---|---|
| IDTA303 | CH | phenyl | H | H | methyl | methyl | phenyl | C(CN)₂ |
| IDTA304 | CH | benzyl | H | H | methyl | methyl | tert- | C(CN)₂ |
| | | | | | | | butyl | |
| IDTA322 | CH | 7-phenoxy- | H | H | methyl | methyl | phenyl | C(CN)₂ |
| | | heptyl | | | | | | |

Compound used as Component K2 in the Inventive Photoactive Layers:

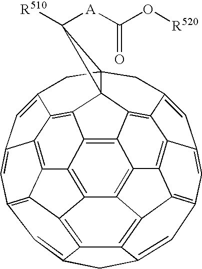

| Abbreviation | R⁵¹⁰ | R⁵²⁰ | A |
|---|---|---|---|
| PCBM | phenyl | methyl | (CH₂)₃ |

Production of the Solar Cells:

General structure: typically, the layers are applied in the sequence of (2) or (3) to (6). In the case of commercially available glass plates coated with ITO (indium tin oxide), the transparent electrode (2) has already been applied to the glass substrate (1).

(1) Transparent substrate: glass plate
(2) Transparent electrode: 140 nm
(3) Hole injection layer: 0-100 nm
(4) Photoactive layer: 30-500 nm
(5) Metal electrode: 0-200 nm
(6) Encapsulation: optional for test structure
(1)+(2): Transparent substrate and transparent electrode

Glass plates coated with approximately 140 nm of ITO (indium tin oxide) from Merck were used. The layer resistance of the ITO was less than 15 Ω.

### (3): Hole Injection Layer:

To improve the surface properties and the hole injection of the ITO anode, the aqueous suspension BAYTRON P VP 14083 from H. C. Starck was used. As well as PEDOT, the suspension also comprises the polymer poly(styrenesulfonic acid) (PSSH). The PEDOT layer thickness was approx. 35 nm. After the spin-coating, the PEDOT layers were baked at 110° C. for two minutes in order to remove water residues.

### (4): Photoactive Layer

The component K1 used was either pure compounds of the formula k1 or mixtures of compounds of the formula k1 (the compounds of the formulae k1 are also referred to hereinafter as “merocyanines”), which had been prepared by syntheses known per se. The component K2 used was the fullerene derivative [6,6]-PCBM shown above ([6,6]-phenyl-C₆₁ butyric acid methyl ester) from Nano-C. To produce the photoactive bulk heterojunction layers of the solar cells investigated, mixtures of the solutions of the individual components K1 and K2 in chlorobenzene were applied by means of spin-coating. The solutions of the individual components were made up in a concentration of 20 g/l just before the layer production and stirred at from 50 to 70° C. overnight. Directly before the spin-coating, the solutions of the individual components were combined and mixed well. The layer thicknesses were controlled principally through the rotational speed and to a lesser extent via the rotation time. The rotational speed was varied within the range from 450 to 2200 rpm; the rotation times were between 20 and 40 seconds. The solvent evaporated in the course of the subsequent heat treatment and/or during the evacuation needed for step (5).

### (5): Metal Electrode

To apply the metal electrode by vapor deposition (so-called “top electrode”, since it constitutes the last active layer in the structure before the encapsulation layer), aluminum, barium and silver were used in granule form with a purity of 99.9%. The top electrode was applied by vapor deposition under a high vacuum of at least 5×10⁻⁶ hPa, in the course of which the evaporation rate was initially kept small (from 0.2 to 0.5 nm/s) and was increased to from 1.0 to 1.5 nm/s only with increasing layer thickness. The aluminum layers applied by vapor deposition had a thickness of about 150 nm.

The following abbreviations are used:
L: thickness of the photoactive layer
V_{OC}: open-circuit voltage
V_{bi}: built-in voltage
V_{OC,ideal}: theoretical open-circuit voltage
J_{SC}: short-circuit current density
FF: filling factor
η: efficiency

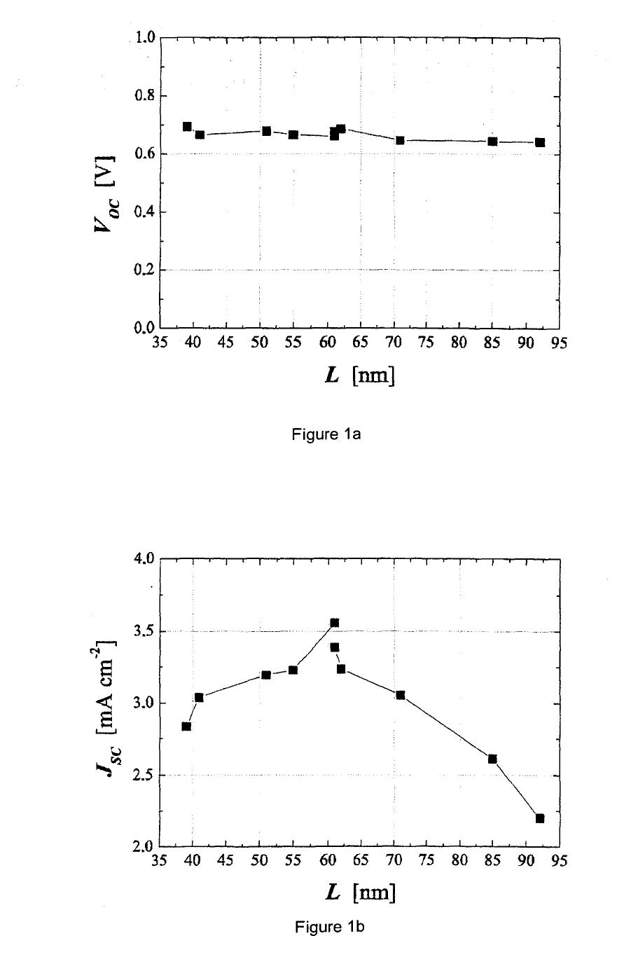

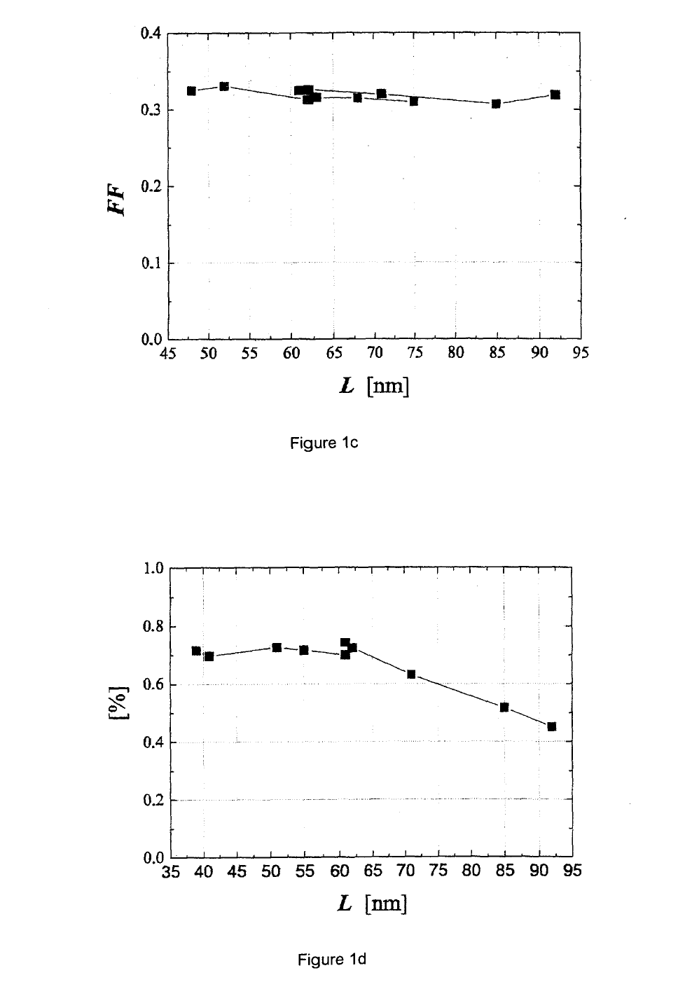

FIGS. 1a to 1d: Plot of the dependence of the characteristics of ATOP4: PCBM solar cells with an ATOP4:PCBM mass ratio of 1:3 on the layer thickness L of the photoactive layer.

FIG. 1a: Dependence of the open-circuit voltage V_{OC} (in V) on the layer thickness L (in nm)

FIG. 1b: Dependence of the short-circuit current density J_{SC} (in mA/cm²) on the layer thickness L (in nm)

FIG. 1c: Dependence of the filling factor FF on the layer thickness L (in nm)

FIG. 1d: Dependence of the efficiency (in %) on the layer thickness L (in nm)

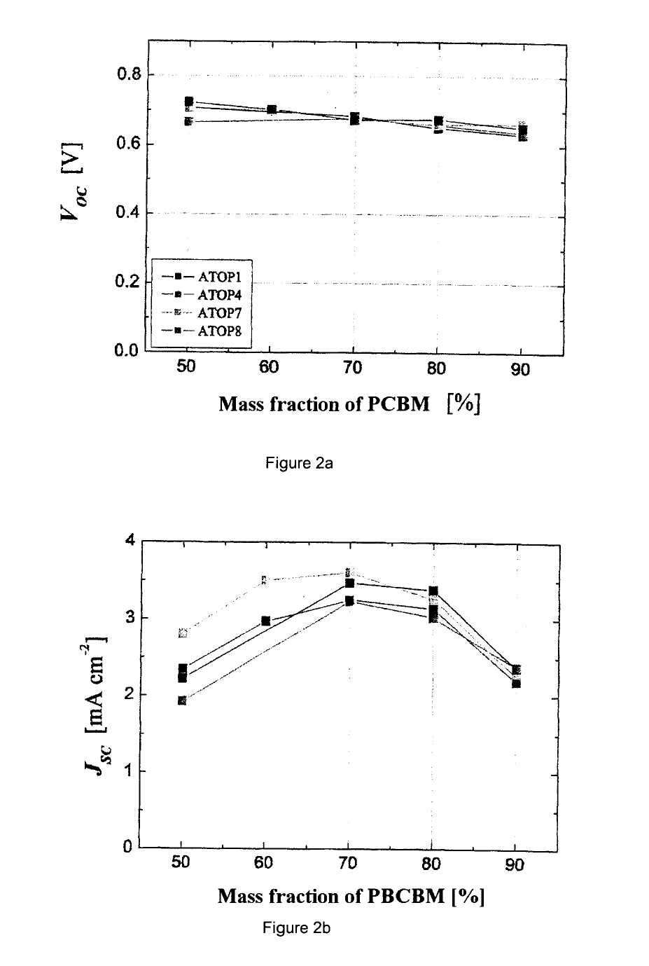

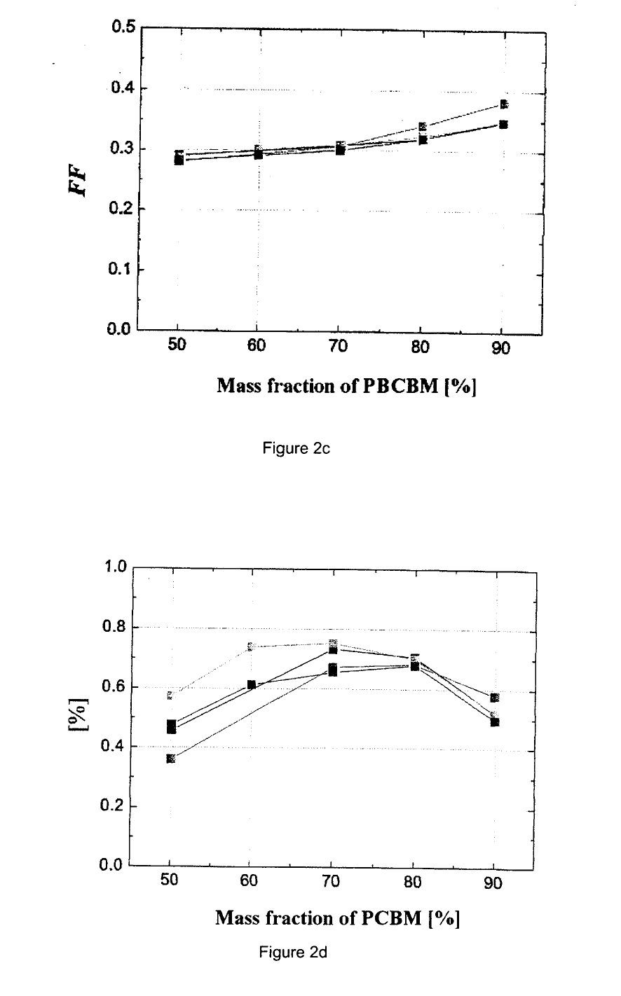

FIGS. 2a to 2d: Plot of the dependence of the characteristics of solar cells comprising the ATOP derivatives ATOP1, ATOP4, ATOP7 and ATOP8 on the mass fraction of ATOP derivative:PCBM (the mass fraction of PCBM and particular ATOP derivative add up to 100%).

FIG. 2a: Dependence of the open-circuit voltage V_{OC} (in V) on the mass fraction of PCBM (in %)

FIG. 2b: Dependence of the short-circuit current density J_{SC} (in mA/cm²) on the mass fraction of PCBM (in %)

FIG. 2c: Dependence of the filling factor FF on the mass fraction of PCBM (in %)

FIG. 2d: Dependence of the efficiency (in %) on the mass fraction of PCBM (in %)

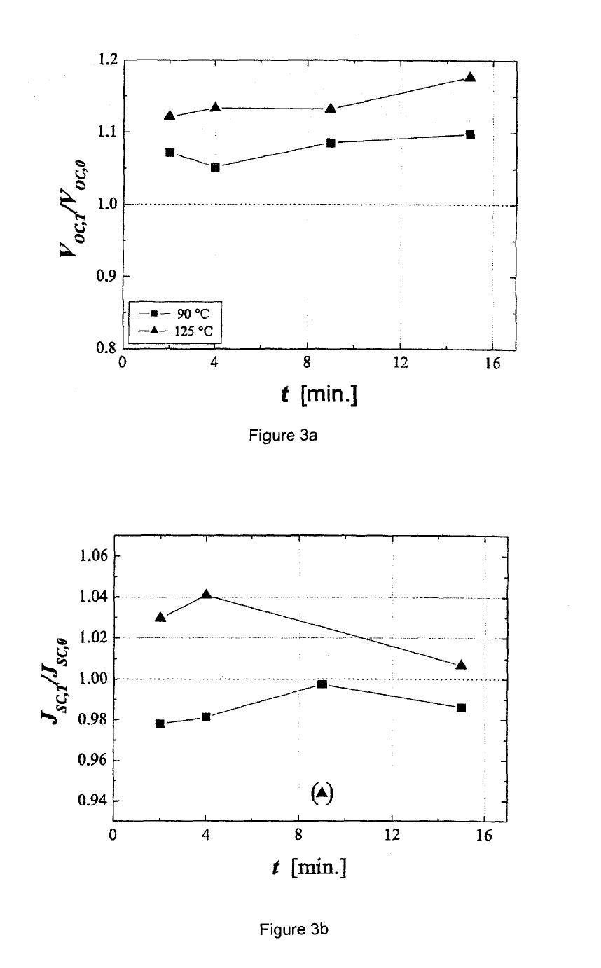

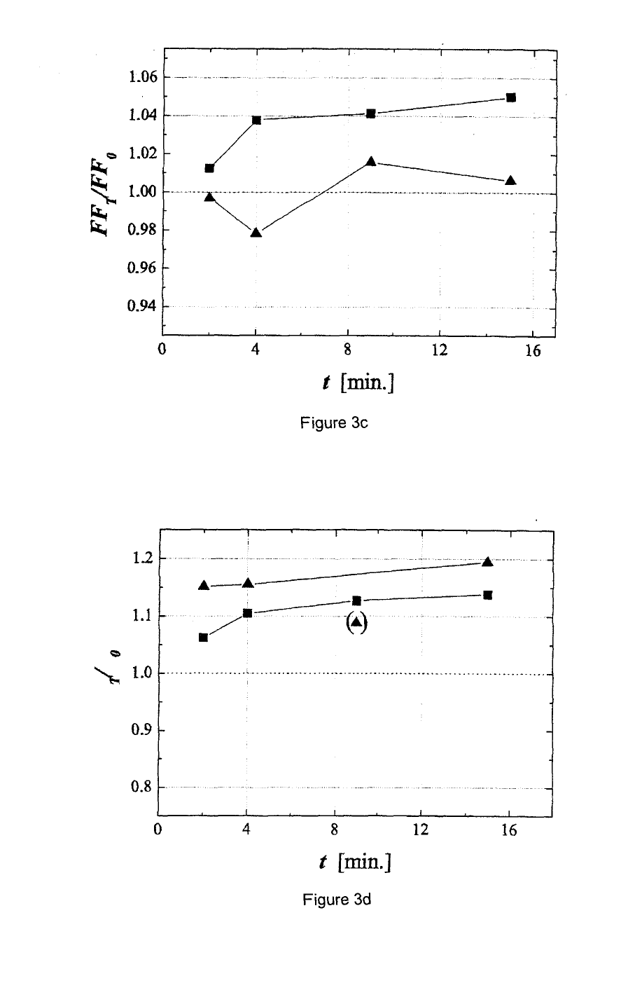

FIGS. 3a to 3d: Plot of the dependence of the relative characteristics of ATOP7:PCBM solar cells with a mass ratio of ATOP7:PCBM of 3:7 on the heat treatment time t (in min). The relative parameters were determined by forming the ratio of the particular characteristic after t min of heat treatment relative to the start value of the characteristic without heat treatment. The heat treatments were performed at 95° C. and 125° C.

The start values without heat treatment can be taken from FIGS. 2a to 2d and are:

V_{OC,0}=0.63 V; J_{SC,0}=3.0 mA cm⁻²; FF₀=0.32; η₀=0.60%

The values of the particular characteristic after t min of heat treatment are denoted by V_{OC,T}, J_{SC,T}, FF_{T} and η_{T}.

Dependence of the V_{OC,T}/V_{OC,0} ratio on the heat treatment time t (in min)

FIG. 3b: Dependence of the J_{SC,T}/J_{SC,0} ratio on the heat treatment time t (in min)

FIG. 3c: Dependence of the FF_{T}/FF₀ ratio on the heat treatment time t (in min)

FIG. 3d: Dependence of the η_{T}/η₀ ratio on the heat treatment time t (in min)

Heat treatment of the layers (after deposition of the electrodes) allowed the characteristics of the cells to be improved somewhat.

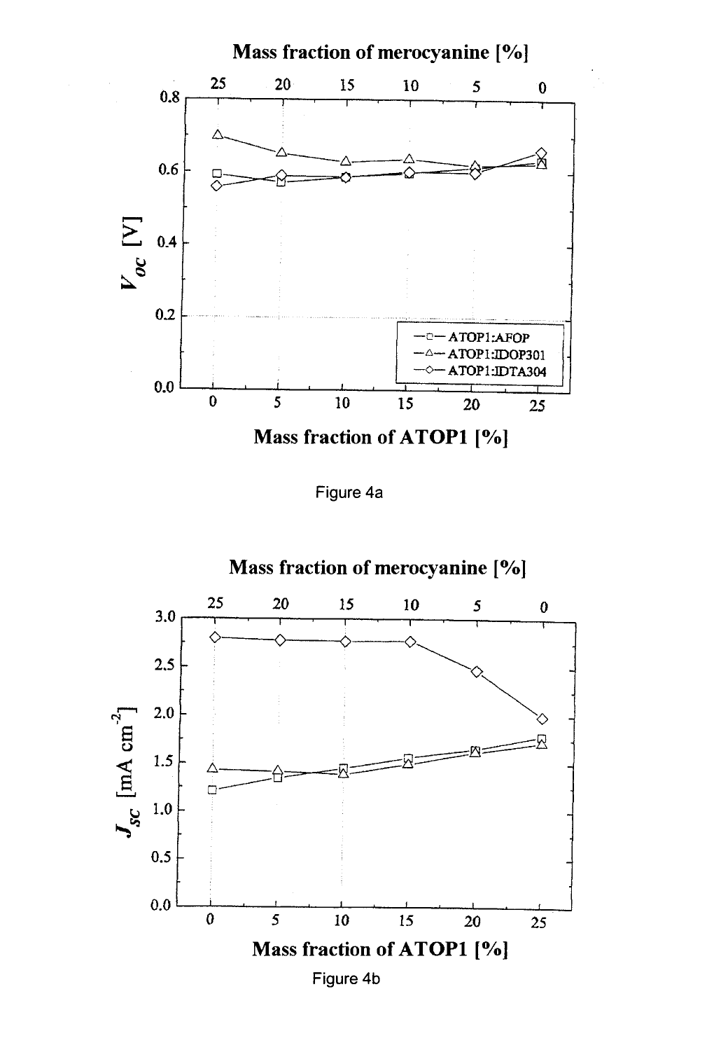

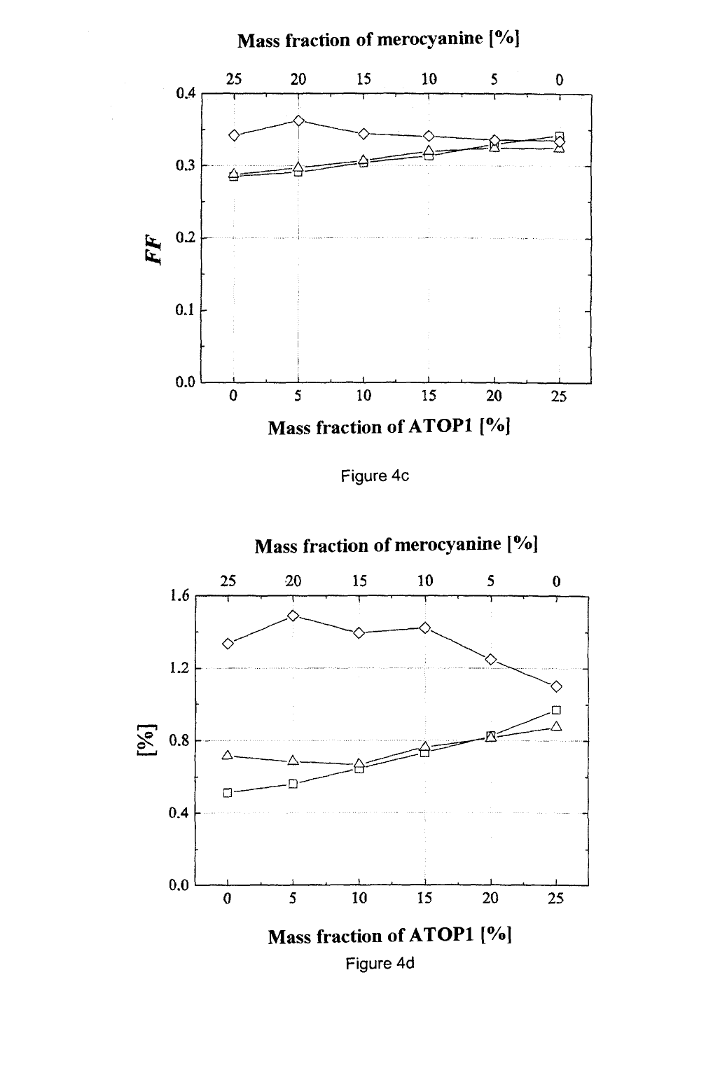

FIGS. 4a to 4d: Plot of the dependence of the characteristics of solar cells on the ATOP1:AFOP, ATOP1:IDOP301 and ATOP1:IDTA304 mass ratio in the photoactive layer. In all cases, a mass ratio of (ATOP1:AFOP):PCBM, (ATOP1:IDOP301):PCBM and (ATOP1:IDTA304):PCBM of 1:3 was established. The mass ratio of the compounds AFOP, IDOP301 and IDTA304 can be taken from the upper abscissa (label “mass fraction of merocyanine [%]”), the mass fraction of the compound ATOP1 from the lower abscissa. The two mass fractions add up in each case to 25%; the mass fraction of PCBM adds up in each case to 100% (according to the ratio of 1:3 stated above).

FIG. 4a: Dependence of the open-circuit voltage V_{OC} (in V) on the ratio of the mass fraction of ATOP1 (in %) to the mass fraction of the particular compounds AFOP, IDOP301 and IDTA304 (in %)

FIG. 4b: Dependence of the short-circuit current density J_{SC} (in mA/cm²) on the ratio of the mass fraction of ATOP1 (in %) to the mass fraction of the particular compounds AFOP, IDOP301 and IDTA304 (in %)

FIG. 4c: Dependence of the filling factor FF on the ratio of the mass fraction of ATOP1 (in %) to the mass fraction of the particular compounds AFOP, IDOP301 and IDTA304 (in %)

FIG. 4d: Dependence of the efficiency (in %) on the ratio of the mass fraction of ATOP1 (in %) to the mass fraction of the particular compounds AFOP, IDOP301 and IDTA304 (in %)

The table which follows lists the characteristics of solar cells with different compounds of the formula D-A (“merocyanine”). In all cases, a mass ratio of merocyanine:PCBM of 1:3 was established.

| | L | V_{OC} | V_{bi} | V_{OC, ideal} | J_{SC} | | η |
|---|---|---|---|---|---|---|---|
| Merocyanine | [nm] | [V] | [V] | [V] | [mA/cm²] | FF | [%] |
| ATOP1 | 66 | 0.63 | 0.66 | 1.57 | 1.79 | 0.34 | 0.97 |
| AFOP | 61 | 0.59 | 0.62 | 1.52 | 1.21 | 0.29 | 0.51 |
| AFOX | 63 | 0.29 | 0.36 | >1.61 | 0.28 | 0.23 | 0.05 |
| IDOP301 | 71 | 0.70 | 0.77 | 1.73 | 1.43 | 0.29 | 0.72 |
| IDTA304 | n.d.¹⁾ | 0.56 | n.d.¹⁾ | 1.52 | 2.80 | 0.34 | 1.34 |
| TAOP | 71 | 0.49 | 0.58 | 1.82 | 0.45 | 0.27 | 0.15 |
| TAOX | 61 | 0.26 | 0.53 | >1.85 | 0.10 | 0.27 | 0.02 |

¹⁾not determined

In the photoactive layers investigated beforehand, component K1 (i.e. the one or more merocyanines of the formula k1) acted as the electron donor and component K2 (i.e. the fullerene derivative) as the electron acceptor.

Analogously to the previous tests, organic solar cells in which the photoactive layer consisted of the compound ATOP4 as component K1 and of the compound poly(3-hexylthiophene) (“P3HT”) as component K2 were produced, the latter compound typically being fhe electron donor. The mass fraction of ATOP4 to P3HT was varied in the range of 1:3, 1:1 and 3:1. The corresponding efficiencies η were found to be 0.02%, 0.03% and 0%. It was found that P3HT in this combination functions again as the electron donor, but ATOP4 as the electron acceptor.

1. An organic solar cell or an organic photodetector comprising:
a photoactive layer, wherein said photoactive layer comprises
K1) one or more compounds of the formula k1
D-A (k1)
as an electron donor or electron acceptor, in which
D is a donor moiety which comprises at least one carbon-carbon or carbon-heteroatom double bond and at least one unfused or fused carbo- or heterocyclic ring,
A is an acceptor moiety which comprises at least one carbon-carbon or carbon-heteroatom double bond and at least one unfused or fused carbo- or heterocyclic ring,
and the donor moiety D and the acceptor moiety A are ir-conjugated to one another,
and
K2) one or more compounds which act correspondingly as electron acceptors or electron donors toward component K1).

2. The photoactive layer according to claim 1, wherein the donor moiety D in the one or more compounds of the formula k1 is selected from the group consisting of: 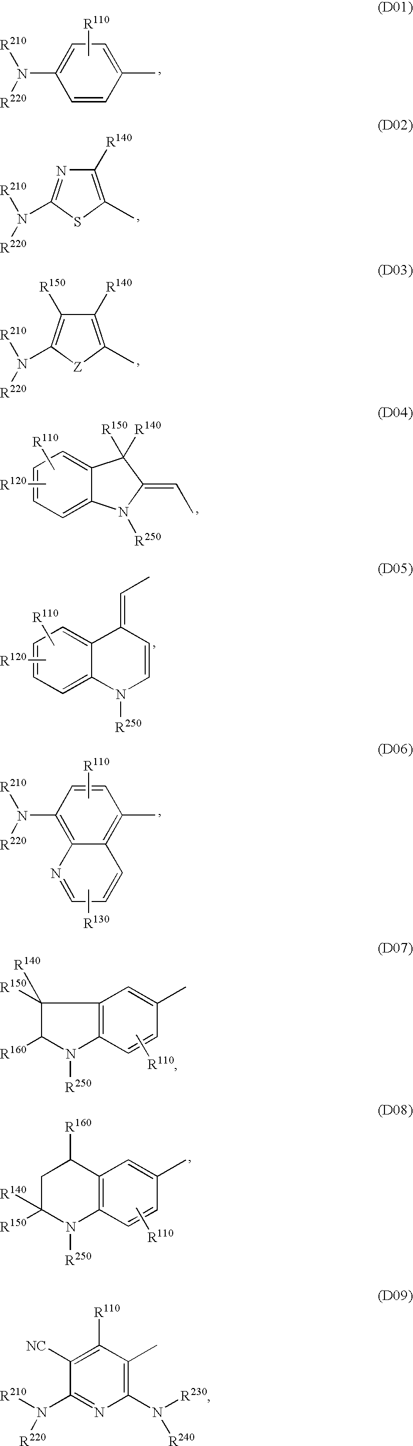 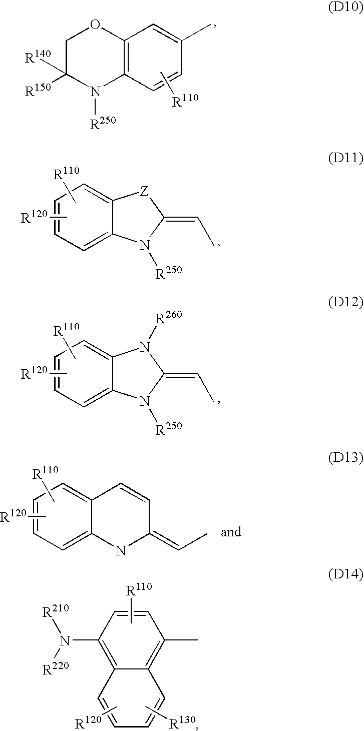
in which
R¹¹⁰, R¹²⁰ and R¹³⁰ are each independently hydrogen, halogen, hydroxyl, C₁-C₁₀ alkyl which may be interrupted by one or two nonadjacent oxygen atoms, C₅-C₇-cycloalkyl, C₁-C₁₀-alkoxy, C₁-C₁₀-alkylamino, di(C₁-C₁₀-alkyl)amino, C₁-C₁₀-alkylamino- or di(C₁-C₁₀-alkyl)aminosulfonylamino, C₁-C₁₀-alkylsulfonylamino, aryl, aryl-C₁-C₁₀-alkyl, aryloxy-C₁-C₁₀-alkyl or an —NHCOR¹⁷⁰ or —NHCOOR¹⁷⁰ radical in which R¹⁷⁰ is defined as aryl, aryl-C₁-C₁₀-alkyl or C₁-C₁₀-alkyl which may be interrupted by one or two nonadjacent oxygen atoms,
R¹⁴⁰, R¹⁵⁰ and R¹⁶⁰ are each independently hydrogen, C₁-C₁₀-alkyl which may be interrupted by one or two nonadjacent oxygen atoms, C₅-C₇-cycloalkyl or aryl,
R²¹⁰, R²²⁰, R²³⁰ and R²⁴⁰ are each independently C₁-C₁₀-alkyl which may be interrupted by one or two nonadjacent oxygen atoms, or C₅-C₁₀-cycloalkyl, or R²¹⁰ and R²²⁰ and/or R²³⁰ and R²⁴⁰ form, together with the nitrogen atom to which they are bonded, a five- or six-membered ring in which one CH₂ group not adjacent to the nitrogen atom may be replaced by an oxygen atom,
R²⁵⁰ and R²⁶⁰ are each independently C₁-C₁₀-alkyl which may be interrupted by one or two nonadjacent oxygen atoms, C₅-C₇-cycloalkyl, aryl, aryl-C₁-C₁₀-alkyl or aryloxy-C₁-C₁₀-alkyl
and
Z is O or S.

3. The photoactive layer according to claim 1, wherein the acceptor moiety A in the one or more compounds of formula k1 is selected from the group consisting of: 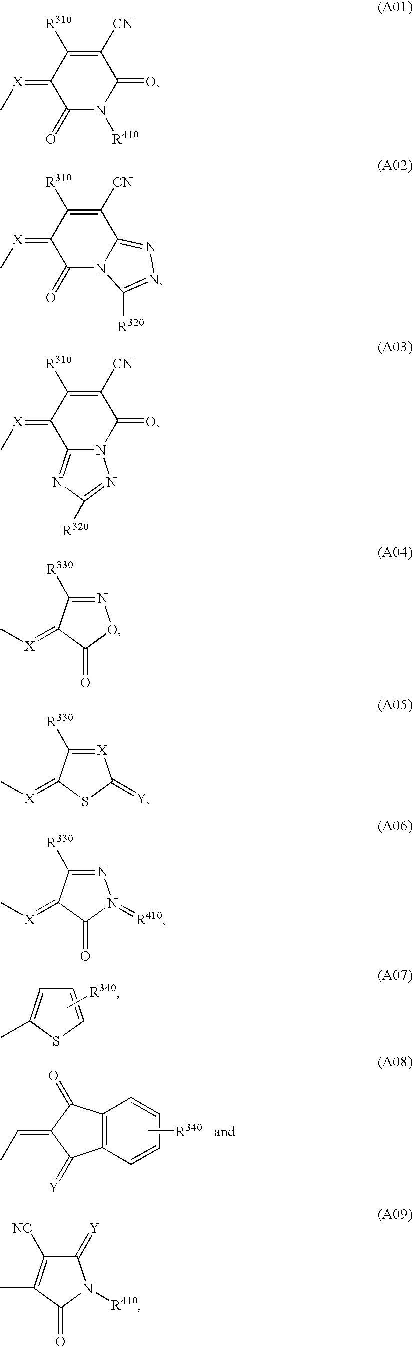
in which
R³¹⁰ and R³²⁰ are each independently hydrogen, C₁-C₁₀-alkyl which may be interrupted by one or two nonadjacent oxygen atoms, or C₅-C₇-cycloalkyl,
R³³⁰ is hydrogen, C₁-C₁₀-alkyl which may be interrupted by one or two nonadjacent oxygen atoms, partly fluorinated C₁-C₁₀-alkyl, perfluorinated C₁-C₁₀-alkyl, C₅-C₇-cycloalkyl or aryl,
R³⁴⁰ is hydrogen, NO₂, CN, COR³⁵⁰, COOR³⁵⁰, SO₂R³⁵⁰ or SO₃R³⁵⁰, in which R³⁵⁰ is defined as aryl or C₁-C₁₀-alkyl,
R⁴¹⁰ is C₁-C₁₀-alkyl which may be interrupted by one or two nonadjacent oxygen atoms, C₅-C₇-cycloalkyl, aryl, aryl-C₁-C₁₀-alkyl, aryloxy-C₁-C₁₀-alkyl, an —NHCOR⁴²⁰ radical or an —N(CO R⁴²⁰)₂ radical, in which R⁴²⁰ is defined as aryl, aryl-C₁-C₁₀-alkyl or C₁-C₁₀-alkyl which may be
Preliminary Amendment
interrupted by one or two nonadjacent oxygen atoms, and the two R⁴²⁰ in the N(CO R⁴²⁰)₂ radical may be the same or different,
X is independently CH or N
and
Y is O, C(CN)₂ or C(CN)(COOR⁴³⁰) in which R⁴³⁰ is defined as C₁-C₁₀-alkyl which may be interrupted by one or two nonadjacent oxygen atoms.

4. The photoactive layer according to claim 1, wherein the one or more compounds of formula k1 in component K1 each have a molecular mass of not more than 1000 g/mol.

5. The photoactive layer according to claim 1, wherein component K2 comprises one or more fullerenes, fullerene derivatives, or mixtures thereof.

6. The photoactive layer according to claim 1, wherein component K2 comprises one or more C₆₀-fullerene derivatives of the general formula k2 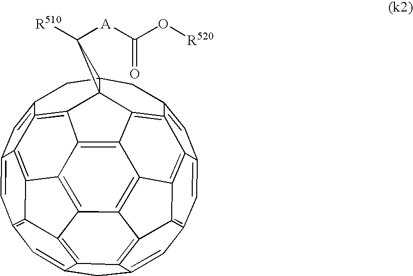
in which
A is C₁-C₁₀-alkylene,
R⁵¹⁰ is aryl or aryl-C₁-C₁₀-alkyl
and
R⁵²⁰ is C₁-C₁₀-alkyl.

7. The photoactive layer according to claim 1, wherein component K1 is present in a proportion of from 10 to 90% by mass, and component K2 in a proportion of from 90 to 10% by mass, where the proportions of components K1 and K2, based in each case on the overall composition of components K1 and K2, add up to 100% by mass.

8. (canceled)

9. A mixture comprising
K1) one or more compounds of the general formula k1
D-A (k1)
in which
D is a donor moiety which comprises at least one carbon-carbon or carbon-heteroatom double bond and at least one unfused or fused carbo- or heterocyclic ring,
A is an acceptor moiety which comprises at least one carbon-carbon or carbon-heteroatom double bond and at least one unfused or fused carbo- or heterocyclic ring,
and the donor moiety D and the acceptor moiety A are 7r-conjugated to one another,
and
K2) one or more fullerenes fullerene derivatives, or both.

10. The mixture according to claim 9, wherein component K2 comprises one or more C₆₀-fullerene derivatives of formula k2 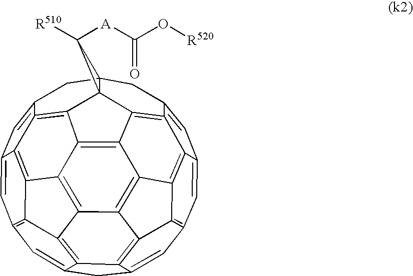
in which
A is C₁-C₁₀-alkylene,
R⁵¹⁰ is aryl or aryl-C₁-C₁₀-alkyl and
R⁵²⁰ is C₁-C₁₀-alkyl.

11. The mixture according to claim 9, wherein the donor moiety D in the one or more compounds of formula k1 is selected from the group consisting of: 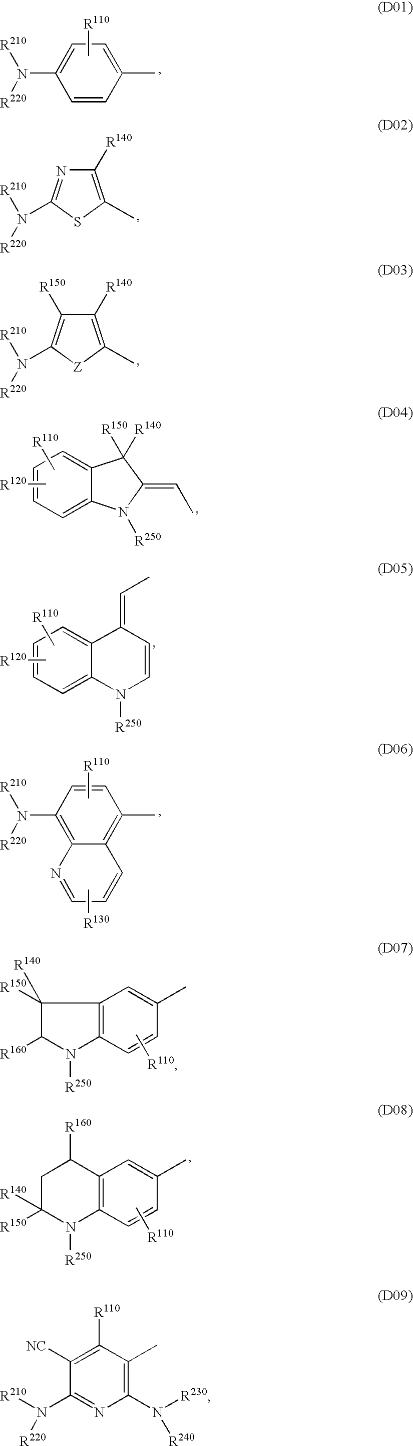 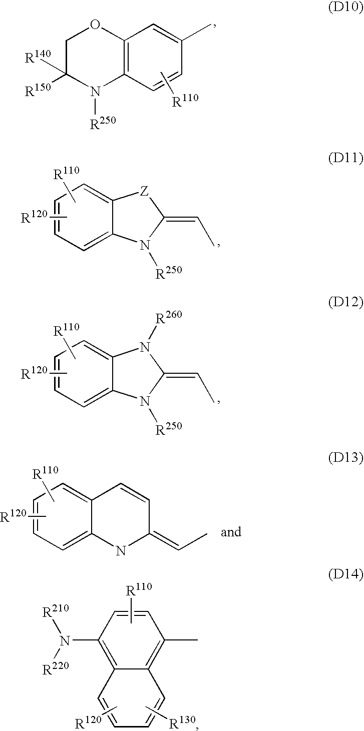
in which
R¹¹⁰, R¹²⁰ and R¹³⁰ are each independently hydrogen, halogen, hydroxyl, C₁-C₁₀-alkyl which may be interrupted by one or two nonadjacent oxygen atoms, C₅-C₇-cycloalkyl, C₁-C₁₀-alkoxy, C₁-C₁₀-alkylamino, di(C₁-C₁₀-alkyl)amino, C₁-C₁₀-alkyl amino- or di(C₁-C₁₀-alkyl)aminosulfonylamino, C₁-C₁₀-alkylsulfonylamino, aryl, aryl-C₁-C₁₀-alkyl, aryloxy-C₁-C₁₀-alkyl or an —NHCOR¹⁷⁰ or —NHCOOR¹⁷⁰ radical in which R¹⁷⁰ is defined as aryl, aryl-C₁-C₁₀-alkyl or C₁-C₁₀-alkyl which may be interrupted by one or two nonadjacent oxygen atoms,
R¹⁴⁰, R¹⁵⁰ and R¹⁶⁰ are each independently hydrogen, C₁-C₁₀-alkyl which may be interrupted by one or two nonadjacent oxygen atoms, C₅-C₇-cycloalkyl or aryl,
R²¹⁰, R²²⁰, R²³⁰ and R²⁴⁰ are each independently C₁-C₁₀-alkyl which may be interrupted by one or two nonadjacent oxygen atoms, or C₅-C₇-cycloalkyl, or R²¹⁰ and R²²⁰ and/or R²³⁰ and R²⁴⁰ form, together with the nitrogen atom to which they are bonded, a five- or six-membered ring in which one CH₂ group not adjacent to the nitrogen atom may be replaced by an oxygen atom,
R²⁵⁰ and R²⁶⁰ are each independently C₁-C₁₀-alkyl which may be interrupted by one or two nonadjacent oxygen atoms, C₅-C₇-cycloalkyl, aryl, aryl-C₁-C₁₀-alkyl or aryloxy-C₁-C₁₀-alkyl
and
Z is O or S
and
the acceptor moiety A in the one or more compounds of formula k1 is selected from the group consisting of: 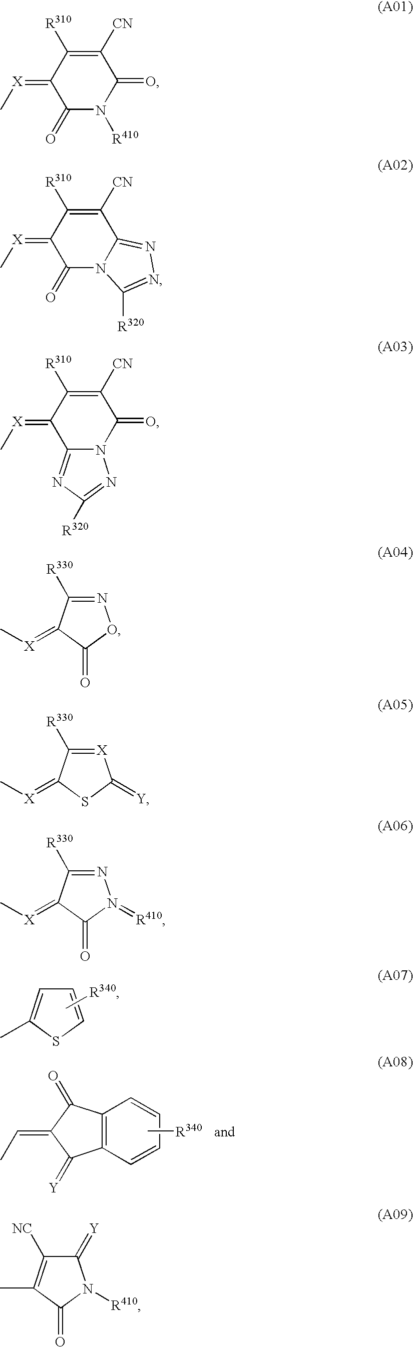
in which
R³¹⁰ and R³²⁰ are each independently hydrogen, C₁-C₁₀-alkyl which may be interrupted by one or two nonadjacent oxygen atoms, or C₅-C₇-cycloalkyl,
R³³⁰ is hydrogen, C₁-C₁₀-alkyl which may be interrupted by one or two nonadjacent oxygen atoms, partly fluorinated C₁-C₁₀-alkyl, perfluorinated C₁-C₁₀-alkyl, C₅-C₇-cycloalkyl or aryl,
R³⁴⁰ is hydrogen, NO₂, CN, COR³⁵⁰, COOR³⁵⁰, SO₂R³⁵⁰ or SO₃R³⁵⁰, in which R³⁵⁰ is defined as aryl or C₁-C₁₀-alkyl,
R⁴¹⁰ is C₁-C₁₀-alkyl which may be interrupted by one or two nonadjacent oxygen atoms, C₅-C₇-cycloalkyl, aryl, aryl-C₁-C₁₀-alkyl, aryloxy-C₁-C₁₀-alkyl, an NHCOR⁴²⁰ radical or an N(CO R⁴²⁰)₂ radical, in which R⁴²⁰ is defined as aryl, aryl-C₁-C₁₀-alkyl or C₁-C₁₀-alkyl which may be interrupted by one or two nonadjacent oxygen atoms, and the two R⁴²⁰ in the —N(CO R⁴²⁰)₂ radical may be the same or different,
X is independently CH or N
and
Y is O, C(CN)₂ or C(CN)(COOR⁴³⁰) in which R⁴³⁰ is defined as C₁-C₁₀-alkyl which may be interrupted by one or two nonadjacent oxygen atoms.

12. The mixture according to claim 9, wherein component K1 is present in a proportion of from 10 to 90% by mass, and component K2 in a proportion of from 90 to 10% by mass, where the proportions of components K1 and K2, based in each case on the overall composition of components K1 and K2, add up to 100% by mass.

13. A method of forming a photoactive layer of an organic solar cell or an organic photodetector, comprising:
mixing
one or more compounds of the formula k1
D-A (k1)
as an electron donor or electron acceptor, in which
D is a donor moiety which comprises at least one carbon-carbon or carbon-heteroatom double bond and at least one unfused or fused carbo- or heterocyclic ring,
A is an acceptor moiety which comprises at least one carbon-carbon or carbon-heteroatom double bond and at least one unfused or fused carbo- or heterocyclic ring,
and the donor moiety D and the acceptor moiety A are 7-conjugated to one another; and
one or more compounds which act correspondingly as electron acceptors or electron donors toward component K1).
